(19) United States
(12) Patent Application Publication
(10) Pub. No.: US 2015/0247911 A1
(43) Pub. Date: Sep. 3, 2015

(54) MAGNETIC RESONANCE SYSTEM AND PROGRAM

(71) Applicant: GE MEDICAL SYSTEMS GLOBAL TECHNOLOGY COMPANY, LLC, Waukesha, WI (US)

(72) Inventor: Yuji Iwadate, Tokyo (JP)

(73) Assignee: GE MEDICAL SYSTEMS GLOBAL TECHNOLOGY COMPANY, LLC, Waukesha, WI (US)

(21) Appl. No.: 14/618,559

(22) Filed: Feb. 10, 2015

(30) Foreign Application Priority Data
Feb. 28, 2014 (JP) 2014039390

(51) Int. Cl. G01R 33/563; G01R 33/385; G01R 33/567; G01R 33/34; G01R 33/341; G01R 33/56; G01R 33/3815

(52) U.S. Cl. CPC G01R 33/56308; G01R 33/5608; G01R 33/385; G01R 33/3815; G01R 33/34092; G01R 33/341; G01R 33/567

(57) ABSTRACT

A magnetic resonance apparatus for performing a scan for generating a first magnetic resonance signal from an imaged part including a moving part is provided. The magnetic resonance apparatus includes a coil having a plurality of channels configured to receive the first magnetic resonance signal, a channel selecting unit configured to select a first channel disposed near an end of the moving part from the plurality of channels, and a generating unit configured to generate a biological signal including motion information indicating a movement of the imaged part in the scan, based on the first magnetic resonance signal received by the first channel.

### CROSS REFERENCE TO RELATED APPLICATIONS

This application claims the benefit of Japanese Patent Application No. 2014-039390 filed Feb. 28, 2014, which is hereby incorporated by reference in its entirety.

### BACKGROUND

The present invention relates to a magnetic resonance apparatus that collects a magnetic resonance signal from an imaged part containing a moving part, and a method for generating a first magnetic resonance signal from an imaged part including a moving part.

A DC self-navigator technique is a known technique of correcting a body motion (see Brau et al., Magnetic Resonance in Medicine 55: 263-270 (2006)).

In the DC self-navigator method, a DC signal indicating data at the center of a k space is collected and is used for correcting a body motion. Moreover, in the DC self-navigator method, the DC signal can be collected using an RF pulse identical to an RF pulse used for collecting an imaging signal. This eliminates the need for considering a spin saturation effect appearing when the imaging signal and a navigator signal are collected with different RF pulses, and thus the DC self-navigator method is suitable for 2D imaging using an RF pulse having a large flip angle (e.g., a 90-degree pulse).

Generally, a magnetic resonance signal for a subject is received using a coil having a plurality of channels. In recent years, coils having multiple channels are particularly used because such coils are suitable for imaging of a wide part.

In the case of the DC self-navigator method, however, a plurality of channels of a coil may include channels unsuitable for detecting a movement of a subject, depending upon the positional relationship between an imaged part and the channels. This makes it difficult to detect a movement of a subject and thus the occurrence of motion artifacts may not be reduced. For this reason, for example, in the case where a subject is imaged using the DC self-navigator method, a method for detecting a movement of a subject as precisely as possible has been demanded.

### BRIEF DESCRIPTION

In a first aspect, a magnetic resonance apparatus for performing a scan for generating a first magnetic resonance signal from an imaged part including a moving part is provided. The magnetic resonance apparatus includes a coil having a plurality of channels that receive the first magnetic resonance signal, a channel selecting unit that selects a first channel disposed near the end of the moving part from the plurality of channels, and a generating unit that generates a biological signal including motion information indicating a movement of the imaged part in the scan, based on the first magnetic resonance signal received by the first channel.

In a second aspect, a program applied to a magnetic resonance apparatus including a scan part that performs a scan for generating a first magnetic resonance signal from an imaged part including a moving part, and a coil having a plurality of channels that receive the first magnetic resonance signal is provided. The program causes a computer to perform channel selection for selecting the first channel disposed near the end of the moving part from the plurality of channels, and generation for generating a biological signal including motion information indicating a movement of the imaged part in the scan, based on the first magnetic resonance signal received by the first channel.

From a plurality of channels, the channel disposed near the end of a moving part can be selected, thereby obtaining more accurate motion information.

Further advantages of the embodiments described herein will be apparent from the following description of exemplary embodiments as illustrated in the accompanying drawings.

### BRIEF DESCRIPTION OF THE DRAWINGS

FIG. 1 is a schematic diagram showing a magnetic resonance apparatus according to a first embodiment.

FIGS. 2A and 2B are explanatory drawings of a coil.

FIGS. 3A and 3B are schematic diagrams showing the positional relationship between channels CH1 to CH4 of a coil portion AC and an imaged part.

FIGS. 4A and 4B are schematic diagrams showing the positional relationship between channels CH5 to CH8 of a coil portion PC and an imaged part.

FIG. 5 is a diagram showing processing performed by a processor 8.

FIG. 6 is an explanatory drawing of scans performed in the first embodiment.

FIG. 7 is a schematic diagram of an example of an image D obtained by a localizer scan LS.

FIG. 8 is a schematic diagram showing n slices L1 to Ln set by an operator.

FIG. 9 is an explanatory drawing of a main scan MS.

FIG. 10 is a diagram showing the operation flow of the MR apparatus in the execution of the localizer scan LS and the main scan MS.

FIG. 11 is an explanatory drawing when sequences C1 to Cn are performed in a period P₁.

FIG. 12 is an explanatory drawing when the sequences C1 to Cn are performed in a period P₂.

FIG. 13 is an explanatory drawing when the sequences C1 to Cn are performed in a period Pₘ.

FIG. 14 is a diagram showing a state in which the sequence C1 is performed in a period P₁.

FIG. 15 is a diagram showing a state in which the sequence C2 is performed in the period P₁.

FIG. 16 is a diagram showing a state in which the sequence Cn is performed in the period P₁.

FIG. 17 is a diagram showing a state in which signals outputted from the channels CH1 to CH8 are combined in the period P₁.

FIG. 18 is a diagram showing an integrated value 51 of a composite signal A₁.

FIG. 19 is an explanatory drawing when a respiratory signal is calculated in the period P₂.

FIG. 20 is a schematic diagram showing the respiratory signal in each of the periods.

FIGS. 21A-21I are diagrams showing the respiratory signal.

FIGS. 22A and 22B are schematic diagrams showing the positional relationship between the channels CH1 and CH3 and a liver.

FIG. 23 is a schematic diagram showing data registered in a database.

FIG. 24 is an explanatory drawing when the respiratory signal is calculated in the period P₁.

FIG. 25 is an explanatory drawing when the respiratory signal is calculated in the period P₂.

FIG. 26 is a schematic diagram showing the respiratory signal obtained by the method of the first embodiment.

FIG. 27 is an explanatory drawing showing the method of deciding the acceptance and rejection of an imaging signal.

FIG. 28 is an explanatory drawing when imaging signals B₁₁ to B₁ₙ are recollected.

FIG. 29 is an explanatory drawing when the sequences C1 to Cn are performed in a period Pₘ₊₂.

FIG. 30 is an explanatory drawing of processing performed by a processor according to a second embodiment.

FIG. 31 is an explanatory drawing of a scan performed in the second embodiment.

FIG. 32 is an explanatory drawing of a pre-scan PS.

FIG. 33 is a diagram showing the operation flow of an MR apparatus according to the second embodiment.

FIG. 34 is a diagram showing a state in which a DC signal A₀ is received by channels CH1 to CH8.

FIG. 35 is a diagram showing a state in which output signals A₀₁ to A₀₈ of the channels CH1 to CH8 undergo Fourier transformation in z direction.

FIG. 36 is a schematic diagram showing the ranges of profiles F1 to F8 in the z direction and the range of a slice Lc in the z direction.

FIG. 37 is a diagram showing a center position zc.

FIG. 38 is a diagram showing integrated values Sa and Sb calculated for each of the profiles.

FIG. 39 is a diagram showing a calculated ratio between the integrated values for each of the profiles.

FIG. 40 is a diagram showing a database stored in a memory according to a third embodiment.

FIG. 41 is an explanatory drawing of processing performed by a processor according to the third embodiment.

FIG. 42 is a diagram showing the operation flow of an MR apparatus according to the third embodiment.

FIG. 43 is an explanatory drawing of a main scan MS according to the third embodiment.

FIG. 44 is an explanatory drawing of processing performed by a processor according to a fourth embodiment.

FIG. 45 is a diagram showing the operation flow of an MR apparatus according to the fourth embodiment.

FIG. 46 is an explanatory drawing of a pre-scan PS.

FIG. 47 is a diagram showing a state in which output signals A₀₁ to A₀₄ of channels CH1 to CH4 undergo Fourier transformation in z direction.

FIG. 48 is a diagram showing J1 to J4 denoting the ratios of profiles F1 to F4.

### DETAILED DESCRIPTION

Exemplary embodiments will be described below. The disclosure is not limited to the following exemplary embodiments.

### (1) First Embodiment

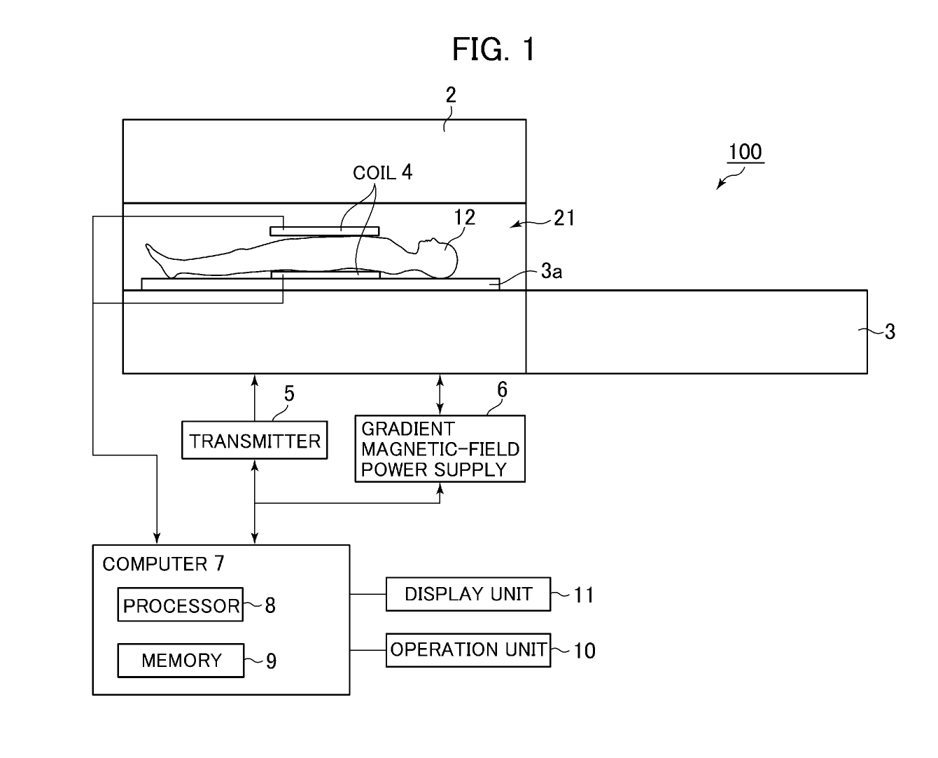

FIG. 1 is a schematic diagram showing a magnetic resonance apparatus according to a first embodiment.

A magnetic resonance apparatus (hereinafter, will be called “MR apparatus”, MR stands for magnetic resonance) includes a magnet 2, a table 3, and a receiving RF coil (hereinafter, will be simply called “coil”).

The magnet 2 includes a bore 21 that accommodates a subject 12. Furthermore, the magnet 2 includes a superconducting coil, a gradient coil, and an RF coil (not shown). The superconducting coil forms a static magnetic field, the gradient coil applies a gradient magnetic field, and the RF coil transmits an RF pulse.

The table 3 has a cradle 3a. The cradle 3a is configured so as to move into the bore 21. The subject 12 is transported into the bore 21 by the cradle 3a.

The coil 4 is attached to the body of the subject 2.

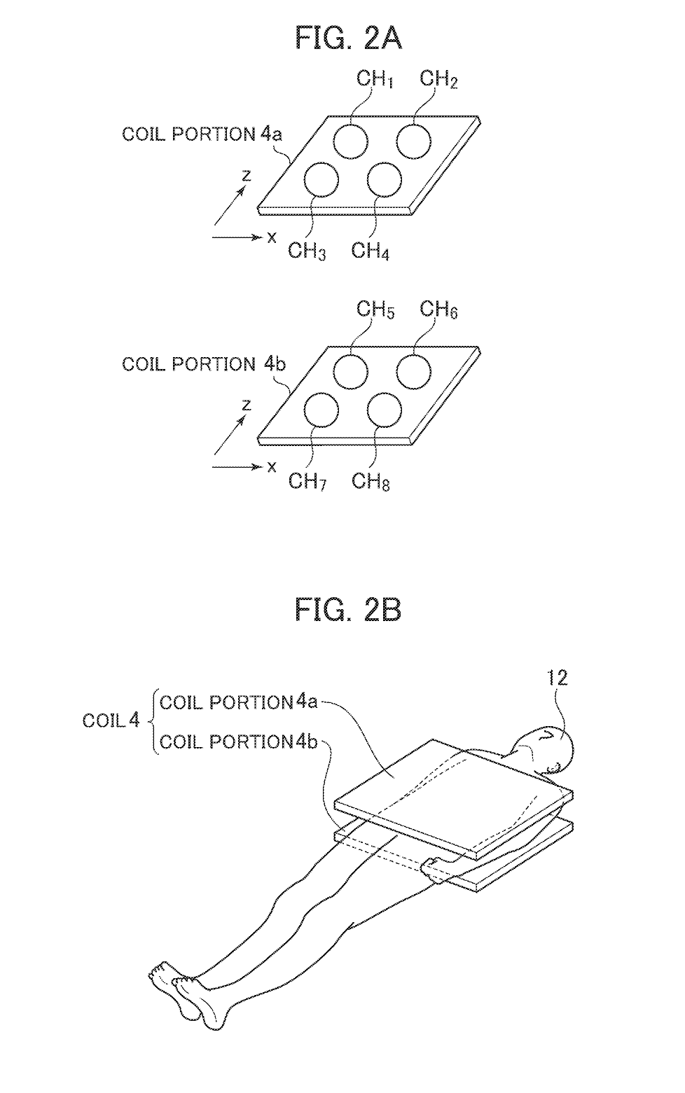

FIGS. 2A and 2B are explanatory drawings of the coil 4.

The coil 4 includes a coil portion 4a and a coil portion 4b. The coil portion 4a is disposed at the front (abdominal side) of the subject and has four channels CH1, CH2, CH3, and CH4. The four channels CH1 to CH4 are arranged in two rows and two columns.

The coil portion 4b is disposed at the rear (back side) of the subject 12 and has four channels CH5, CH6, CH7, and CH8. The four channels CH5 to CH8 are arranged in two rows and two columns.

In the first embodiment, an organ to be imaged is a liver and thus the coil portions 4a and 4b are attached near the liver.

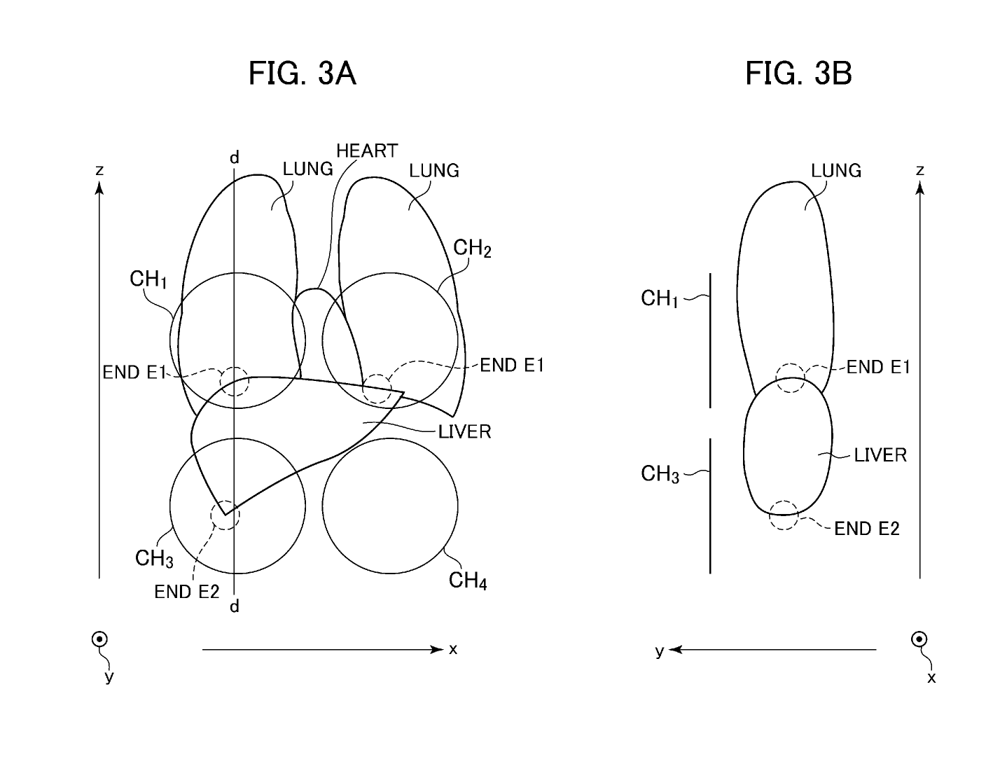

FIGS. 3A and 3B are schematic diagrams showing the positional relationship between the channels CH1 to CH4 of the coil portion 4a and an imaged part. FIG. 3A shows the positions of the channels in a plane zx. FIG. 3B shows the positions of the channels in a cross section taken along line d-d of FIG. 3A.

The channels CH1 and CH2 are arranged in the x direction, while the channels CH3 and CH4 are also arranged in the x direction. The channel CH3 is located at the same position as the channel CH1 in the x direction but at a different position from the channel CH1 in the z direction. The channel CH4 is located at the same position as the channel CH2 in the x direction but at a different position from the channel CH2 in the z direction. The channels CH1 and CH2 are located near an end E1 of a liver, whereas the channels CH3 and CH4 are separated from the end E1 of the liver in the −z direction. For example, the channel CH3 is located near an end E2 on the opposite side of the liver from lungs.

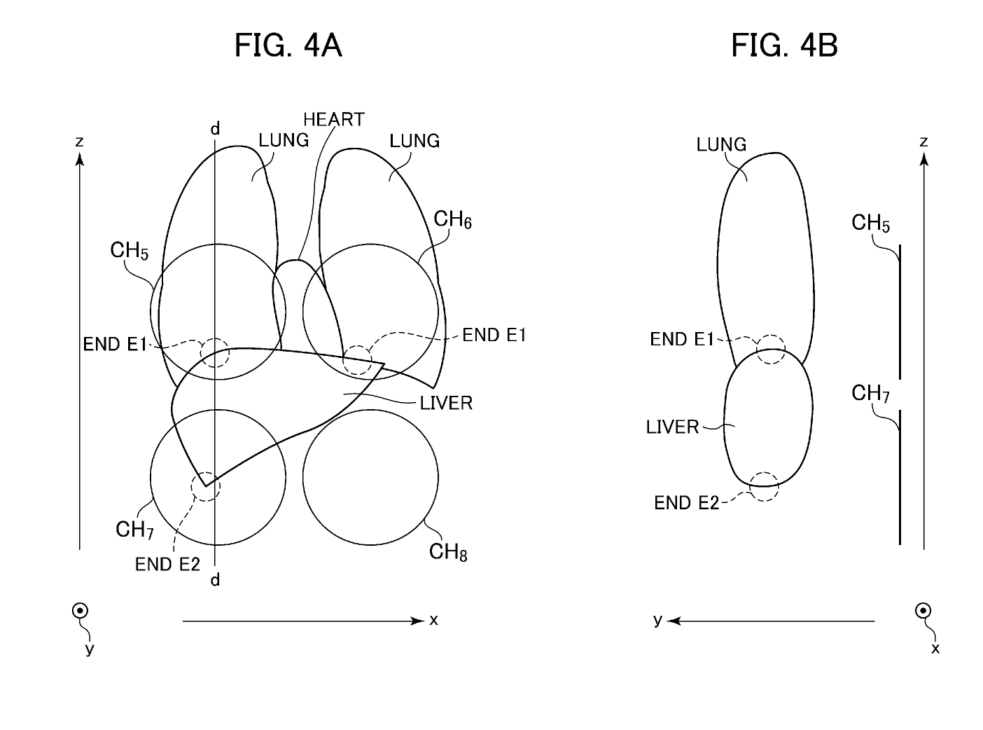

FIGS. 4A and 4B are schematic diagrams showing the positional relationship between channels CH5 to CH8 of the coil portion 4b and an imaged part. FIG. 4A shows the positions of the channels in the zx plane. FIG. 4B shows the positions of the channels in a cross section taken along line d-d of FIG. 4A.

The channels CH5 and CH6 are arranged in the x direction, while the channels CH7 and CH8 are also arranged in the x direction. The channel CH7 is located at the same direction as the channel CH5 in the x direction but at a different position from the channel CH5 in the z direction. The channel CH8 is located at the same position as the channel CH6 in the x direction but at a different position from the channel CH8 in the z direction. The channels CH5 and CH6 are located near the end E1 of the liver, whereas the channels CH7 and CH8 are separated from the end E1 of the liver in the −z direction.

Referring to FIG. 1 again, the MR apparatus 100 will be further discussed.

The MR apparatus 100 further includes a transmitter 5, a gradient magnetic-field power supply 6, a computer 7, an operation unit 10, and a display unit 11.

The transmitter 5 supplies a current to the RF coil while the gradient magnetic-field power supply 6 supplies a current to the gradient coil. The magnet 2, the transmitter 5, and the gradient magnetic-field power supply 6 are combined into a scan unit.

The computer 7 controls the operations of the parts of the MR apparatus 100 so as to realize the operations of the MR apparatus 100. For example, the computer 7 transmits information necessary for the display unit 11 and reconstructs an image. The computer 7 includes a processor 8 and a memory 9.

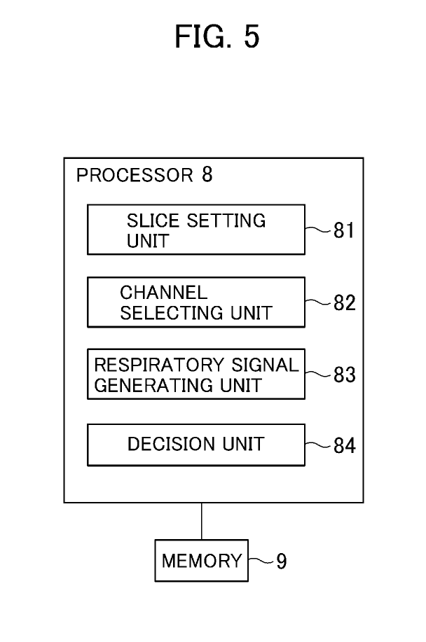

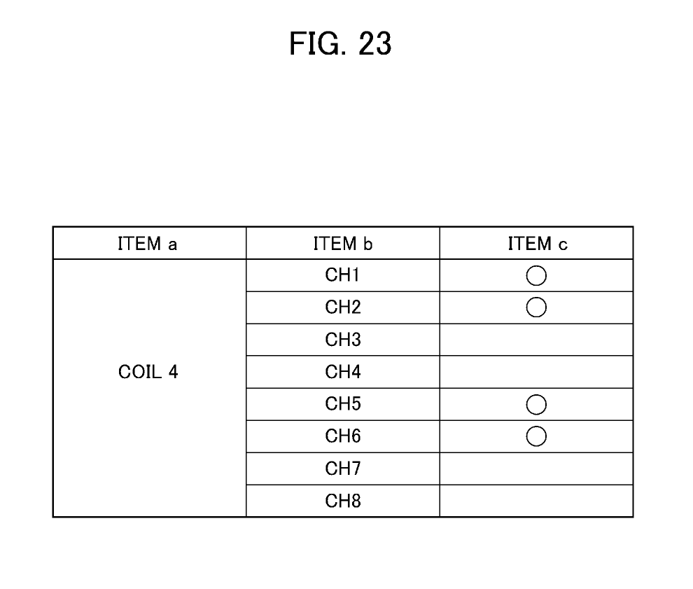

The memory 9 contains programs executed by the processor 8 and a database (FIG. 23), which will be discussed later. The processor 8 reads the programs contained in the memory 9 and executes processing described in the programs. FIG. 5 is a diagram showing processing performed by the processor 8. The processor 8 reads the programs contained in the memory 9 and realizes functions from a slice setting unit 81 to a decision unit 84.

The slice setting unit 81 sets a slice based on information inputted from the operation unit 10.

The channel selecting unit 82 selects the channels disposed near the end E1 of the liver (FIGS. 3A and 3B) from the channels CH1 to CH8 included in the coil 4, based on the database which will be described later.

The respiratory signal generating unit 83 generates a respiratory signal based on the received signals of the channels selected by the channel selecting unit 82.

The decision unit 84 decides whether or not an imaging signal should be accepted as an image reconstruction signal.

The processor 8 executes predetermined programs so as to function as these units.

The operation unit 10 is operated by an operator to input various kinds of information to the computer 7. The display unit 11 displays various kinds of information.

The MR apparatus 100 is configured thus.

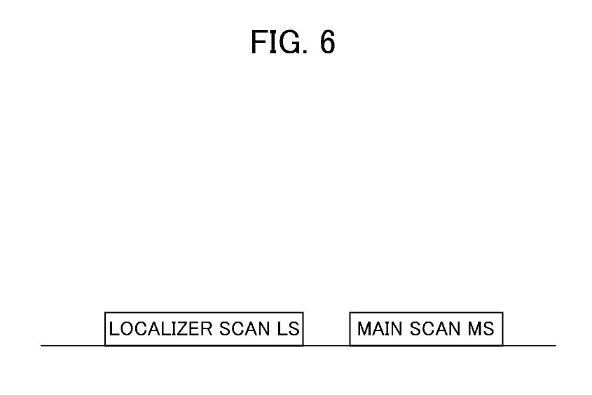

FIG. 6 is an explanatory drawing of scans performed in the first embodiment.

In the first embodiment, a localizer scan LS and a main scan MS are performed.

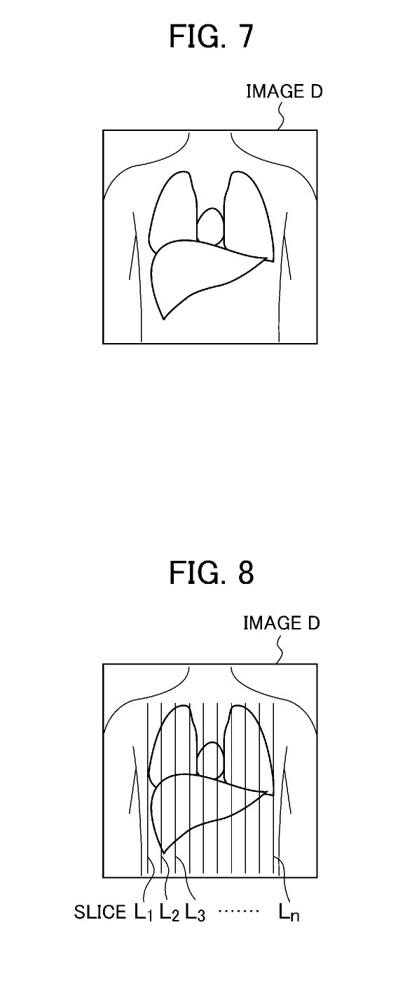

The localizer scan LS is a scan for obtaining an image D that is used for setting a slice. In the localizer scan LS, an axial image, a sagittal image, and a coronal image are obtained. FIG. 7 only shows a coronal image as the image D obtained by the localizer scan LS.

The operator sets a slice based on the image D. FIG. 8 is a schematic diagram showing n slices L1 to Ln set by the operator. FIG. 8 shows an example of the setting of sagittal slices. The disclosure is not limited to a sagittal slice and is also applicable to an axial slice, a coronal slice, and an oblique slice. After the slices L1 to Ln are set, the main scan MS is performed.

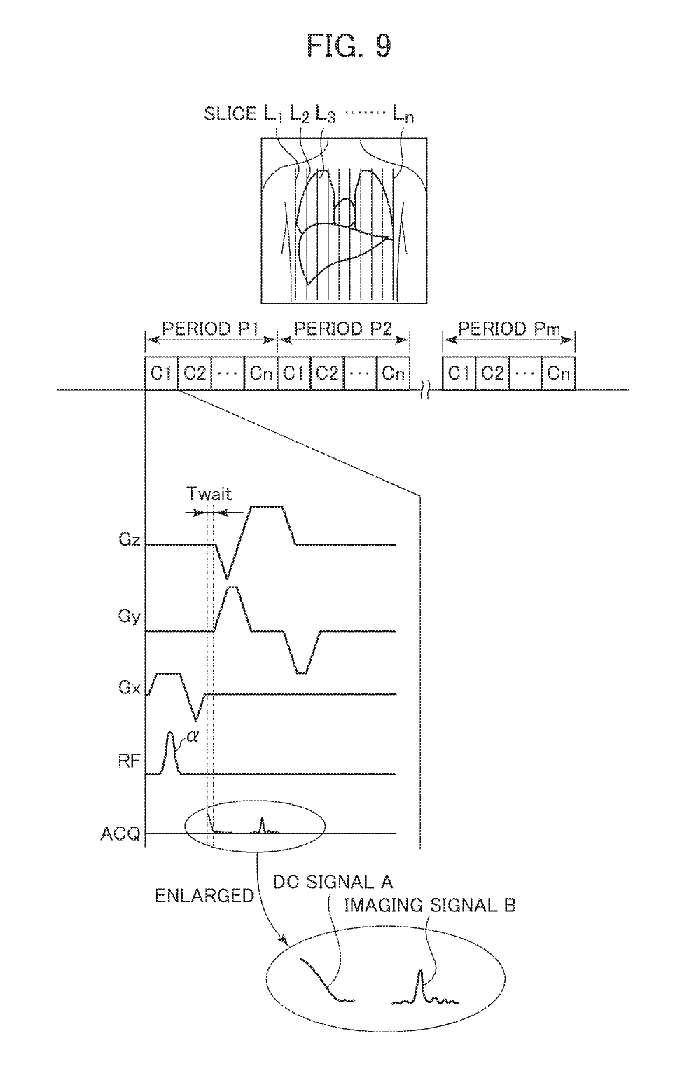

FIG. 9 is an explanatory drawing of the main scan MS.

The main scan MS is a scan for obtaining the images of the n slices L1 to Ln by a multi-slice method. In the main scan MS, sequences C1 to Cn for obtaining the images of the slices L1 to Ln are first performed in a period P₁. FIG. 9 schematically shows an example of the sequence C1. The sequence C1 is configured to collect an MR signal (hereinafter, will be called “DC signal”) A indicating data at the center of a k space and an MR signal (hereinafter, will be called “imaging signal”) B used for creating an image, according to a DC self-navigator method.

The sequence C1 has an RF pulse a for exciting the slice L1. The imaging signal B is collected from the slice L1 excited by the RF pulse α. The RF pulse α is used not only for collecting the imaging signal B but also for collecting the DC signal A. The DC signal A is collected in a waiting time Twait that is set immediately before gradient magnetic fields Gy and Gz are applied. The waiting time Twait is, for example, 20 μs.

After the sequence C1 is performed, the sequences C2 to Cn for obtaining the images of the slices L2 to Ln are sequentially performed. The sequences C2 to Cn are expressed by the same sequence chart as the sequence C1 except for the excitation frequency of the RF pulse α. Thus, in a period P₁, the DC signal A and the imaging signal B are collected each time the sequences C1 to Cn are performed.

After the sequences C1 to Cn are performed in the period P₁, the sequences C1 to Cn are also performed in the subsequent period P₂. The sequences C1 to Cn are repeatedly performed in a similar manner. FIG. 9 shows the sequences C1 to Cn performed in the periods P₁ to Pₘ. A phase encoding amount changes for the sequences C1 to Cn changes in each period.

The operation flow of the MR apparatus in the execution of the localizer scan LS and the main scan MS will be specifically described below.

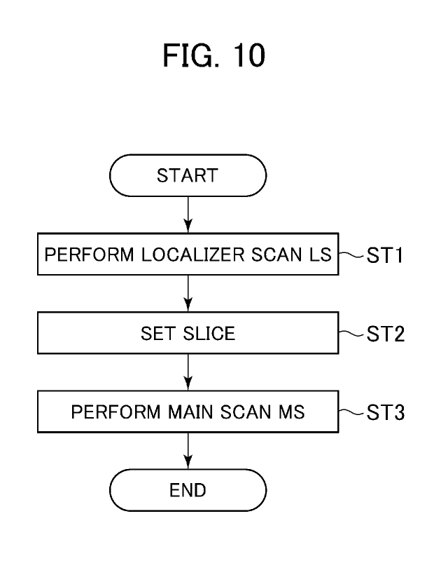

FIG. 10 is a diagram showing the operation flow of the MR apparatus in the execution of the localizer scan LS and the main scan MS.

In step ST1, the localizer scan LS is performed. The image D (FIG. 7) is obtained by performing the localizer scan LS. After the localizer scan LS is performed, the process advances to step ST2.

In step ST2, the operator operates the operation unit 10 (FIG. 1) to input information for setting the slices L1 to Ln (FIG. 8) with reference to the image D. The slice setting unit 81 (FIG. 5) sets the slices L1 to Ln based on the information inputted from the operation unit 10. After the setting of the slices L1 to Ln, the process advances to step ST3.

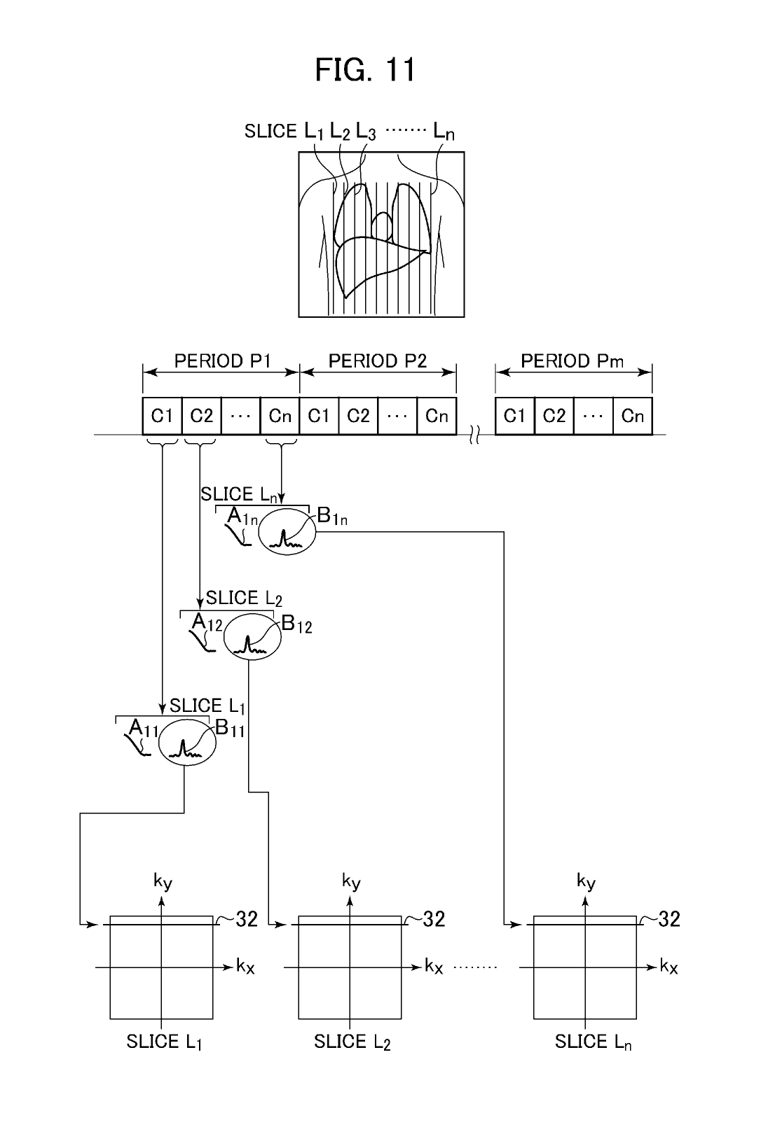

In step ST3, the main scan MS is performed. In the main scan MS, the sequences C1 to Cn are first performed in the period P₁ (FIG. 11).

FIG. 11 is an explanatory drawing when the sequences C1 to Cn are executed in the period P₁.

FIG. 11 schematically shows the DC signal A and the imaging signal B that are collected by performing the sequences C1 to Cn in the period P1. In FIG. 11, the DC signals A obtained in the period P1 are discriminated from one another by adding subscripts “11”, “12”, . . . “1n” to reference character A. Similarly, the imaging signals B are discriminated from one another by adding subscripts “11”, “12”, . . . “1n” to reference character B.

In the period P₁, the sequence C1 is first performed. A DC signal A₁₁ and an imaging signal B₁₁ are collected by performing the sequence C1. The imaging signal B₁₁ is used as data on the line of ky=3 of the slice L1. After the sequence C1 is performed, the sequence C2 is performed. Incidentally, the direction of kx in kx-ky space corresponds to the z direction in FIG. 3A etc.

A DC signal A₁₂ and an imaging signal B₁₂ are collected by performing the sequence C2. The imaging signal B₁₂ is used as data on the line of ky=32 of the slice L2.

After that, the sequences for collecting DC signals and imaging signals from the slices L3 to Ln are sequentially performed in a similar manner. At the end of the period P₁, the sequence Cn for collecting data on the slice Ln is performed. A DC signal A₁ₙ and an imaging signal B₁ₙ are collected by performing the sequence Cn. The imaging signal B₁ₙ is used as data on the line of ky=32 of the slice Ln.

Thus, in the period P₁, data on ky=32 of the slices L1 to Ln can be collected. The process advances to the period P₂.

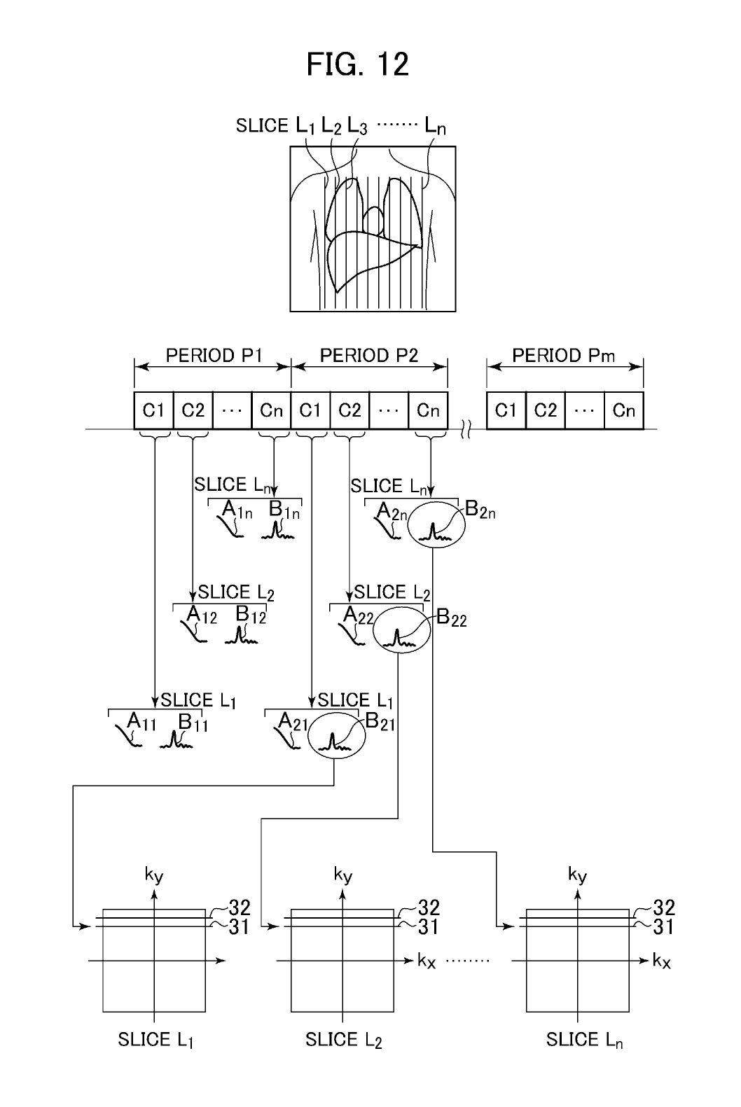

FIG. 12 is an explanatory drawing when the sequences C1 to Cn are performed in the period P₂.

In FIG. 12, the DC signals A obtained in the period P₂ are discriminated from one another by adding subscripts “21”, “22”, . . . “2n” to reference character A. Similarly, the imaging signals B are discriminated from one another by adding subscripts “21”, “22”, . . . “2n” to reference character B.

In the period P₂, the sequence C1 is first performed. A DC signal A₂₁ and an imaging signal B₂₁ are collected by performing the sequence C1. The imaging signal B₂₁ indicates data on the line of ky=31 of the slice L1. After the sequence C1 is performed, the sequences C2 to Cn are sequentially performed. Thus, data on ky=31 of the slices L1 to Ln can be collected in the period P₂.

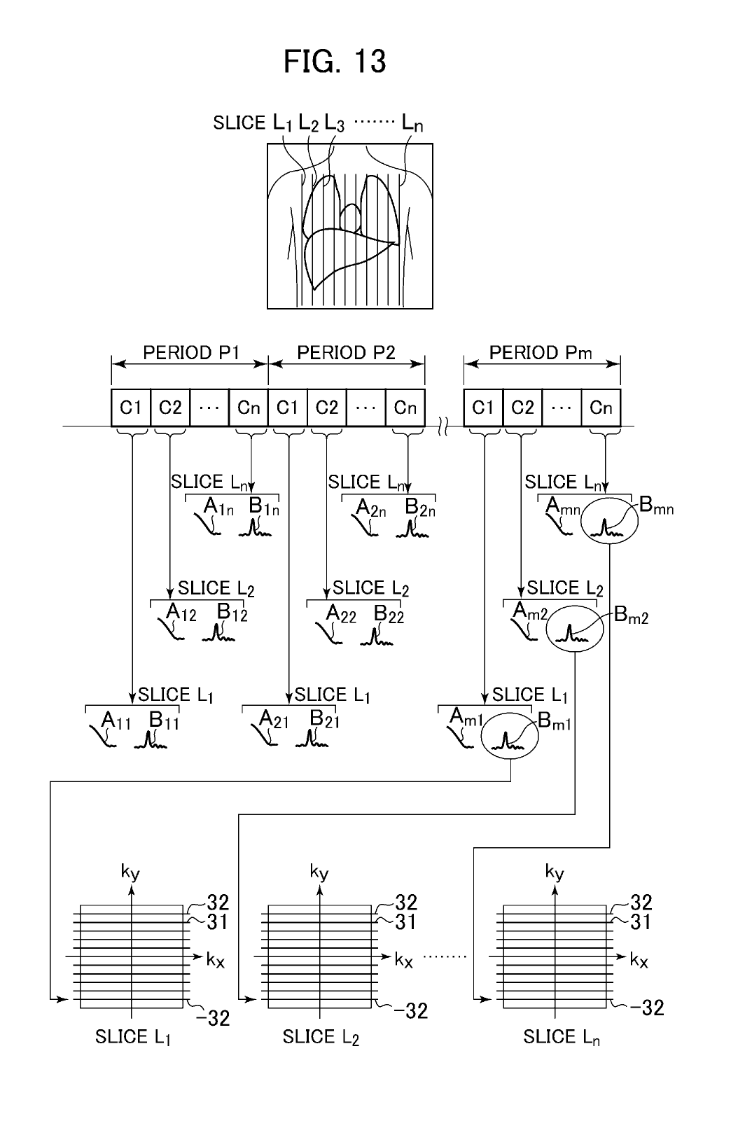

Even after the data on ky=31 is collected in the period P₂, the sequences C1 to Cn for collecting data on other ky views are repeatedly performed (FIG. 13).

FIG. 13 is an explanatory drawing when the sequences C1 to Cn are performed in the period Pm. In FIG. 13, the DC signals A obtained in the period Pₘ are discriminated from one another by adding subscripts “m1”, “m2”, . . . “mn” to reference character A. Similarly, the imaging signals B are discriminated from one another by adding subscripts “m1”, “m2”, . . . “mn” to reference character B.

In the period Pm, the sequence C1 is first performed. The DC signal Aₘ₁ and the imaging signal Bₘ₁ are collected by performing the sequence C1. The imaging signal Bₘ₁ indicates data on the line of ky=−32 of the slice L1. After the sequence C1 is performed, the sequences C2 to Cn are sequentially performed. Thus, in the period Pm, data on ky=−32 of the slices L1 to Ln can be collected.

The DC signal A can be collected in addition to the imaging signal B by performing the sequences C1 to Cn. In the first embodiment, a respiratory signal of a subject is generated using the DC signal A. A method of generating the respiratory signal according to the first embodiment will be described below. In the explanation of the method of generating the respiratory signal according to the first embodiment, an example of a different method of generating the respiratory signal from the first embodiment will be first discussed to clarify the effect of the method of generating the respiratory signal according to the first embodiment, which is followed by the explanation of the method of generating the respiratory signal according to the first embodiment.

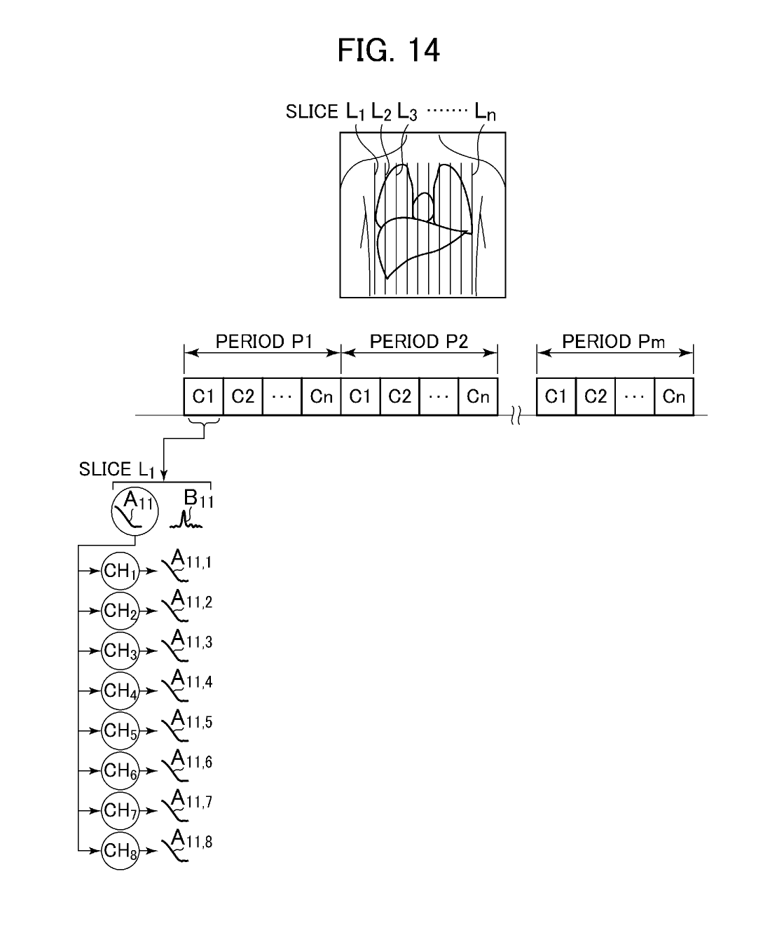

FIGS. 14 to 19 are explanatory drawings of the example of the different method of generating the respiratory signal from the first embodiment.

First, as shown in FIG. 14, the sequence C1 is performed in the period P₁. The DC signal A₁₁ and the imaging signal B₁₁ are collected from the slice L1 by performing the sequence C1.

Since the coil 4 has the channels CH1 to CH8, the DC signal A₁₁ is received by each of the channels CH1 to CH8. In the lower part of FIG. 14, reference numerals “A_{11,1}” to “A_{11,8}” denote signals outputted from the channels CH1 to CH8 that receive the DC signal A₁₁.

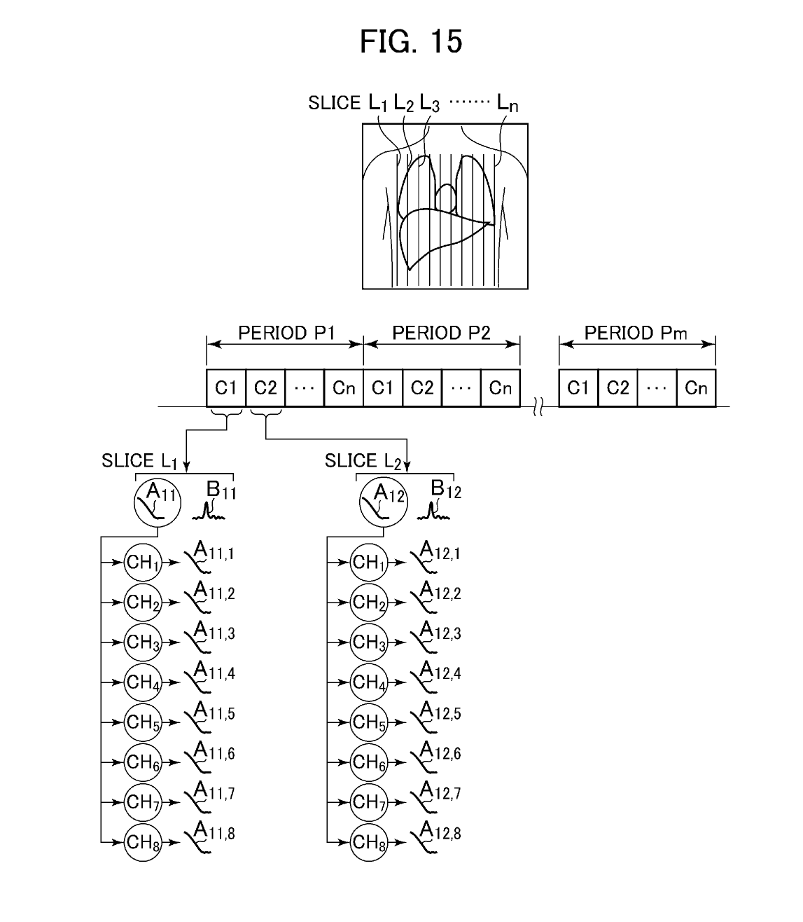

After the sequence C1 is performed, the sequence C2 is performed. FIG. 15 shows a state after the sequence C2 is performed. The DC signal A₁₂ and the imaging signal B₁₂ are collected from the slice L2 by performing the sequence C2.

Since the coil 4 has the channels CH1 to CH8, the DC signal A₁₂ is received by each of the channels CH1 to CH8 like the DC signal A₁₁. In the lower part of FIG. 15, reference numerals “A_{12,1}” to “A_{12,8}” denote signals outputted from the channels CH1 to CH8 that receive the DC signal A₁₂.

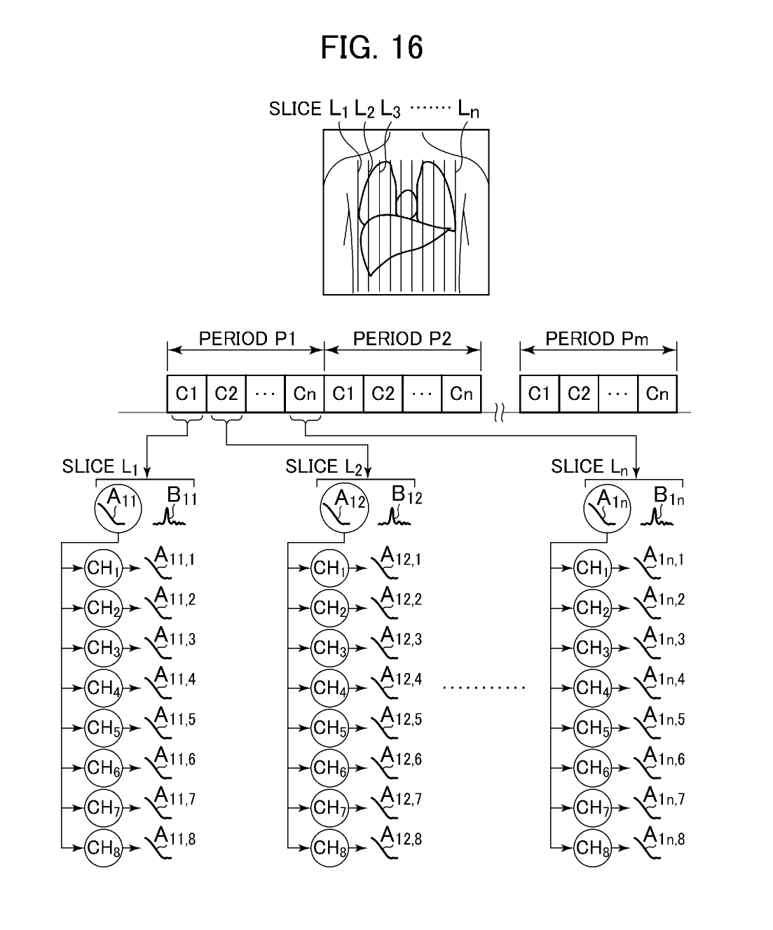

After that, the sequences for collecting the DC signals and the imaging signals from the slices L3 to Ln are similarly performed. At the end of the period P₁, the sequence Cn for collecting data on the slice Ln is performed. FIG. 16 shows a state after the sequence Cn is performed. The DC signal A₁ₙ and the imaging signal B₁ₙ are collected from the slice Ln by performing the sequence Cn.

Since the coil 4 has the channels CH1 to CH8, the DC signal A₁ₙ is received by each of the channels CH1 to CH8 like the DC signal A₁₁. In the lower part of FIG. 16, reference numerals “A_{1n.1}” to “A_{1n.8}” denote signals outputted from the channels CH1 to CH8 that receive the DC signal A₁ₙ.

The DC signals are outputted from the channels each time the sequence is performed.

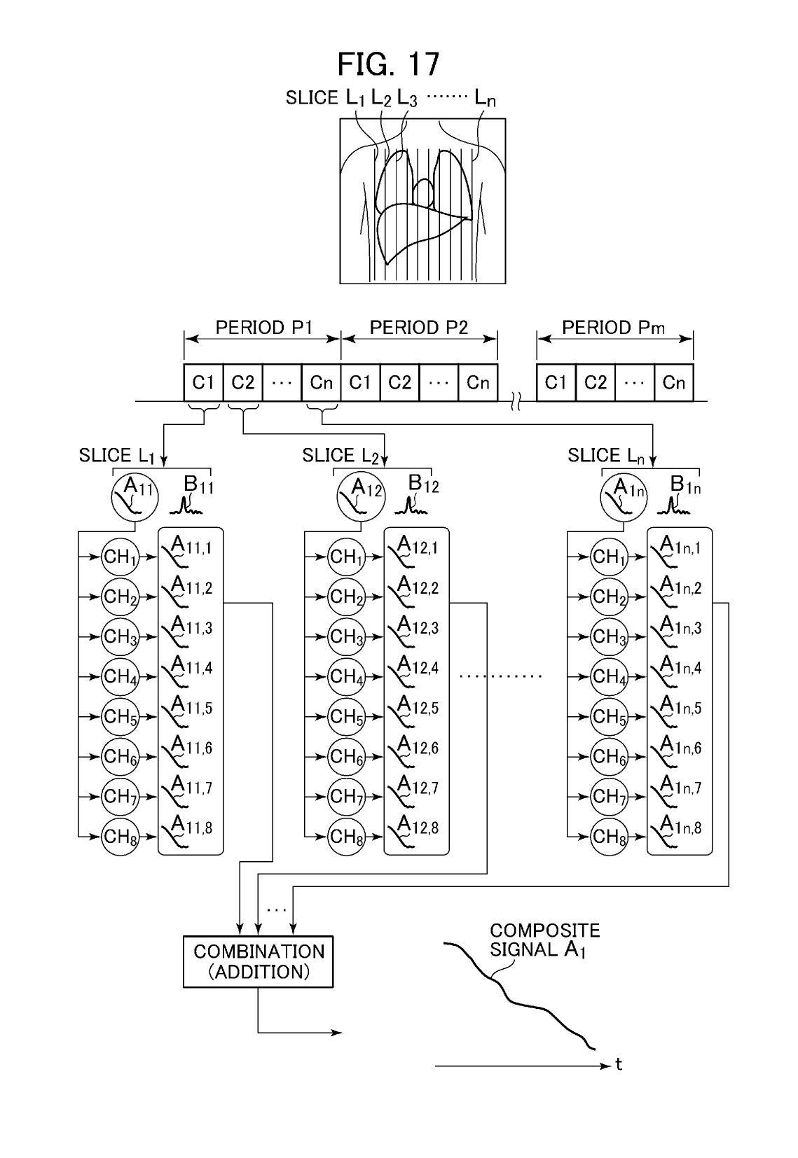

Subsequently, in the period P1, the signals outputted from the channels CH1 to CH8 are combined (FIG. 17).

FIG. 17 is a diagram showing a state in which the signals outputted from the channels CH1 to CH8 are combined in the period P1.

FIG. 17 shows an example in which the signals of the channels CH1 to CH8 are combined by adding the signals outputted from the channels CH1 to CH8 in the period P₁. All the signals of the channels CH1 to CH8 are added to obtain a composite signal A1.

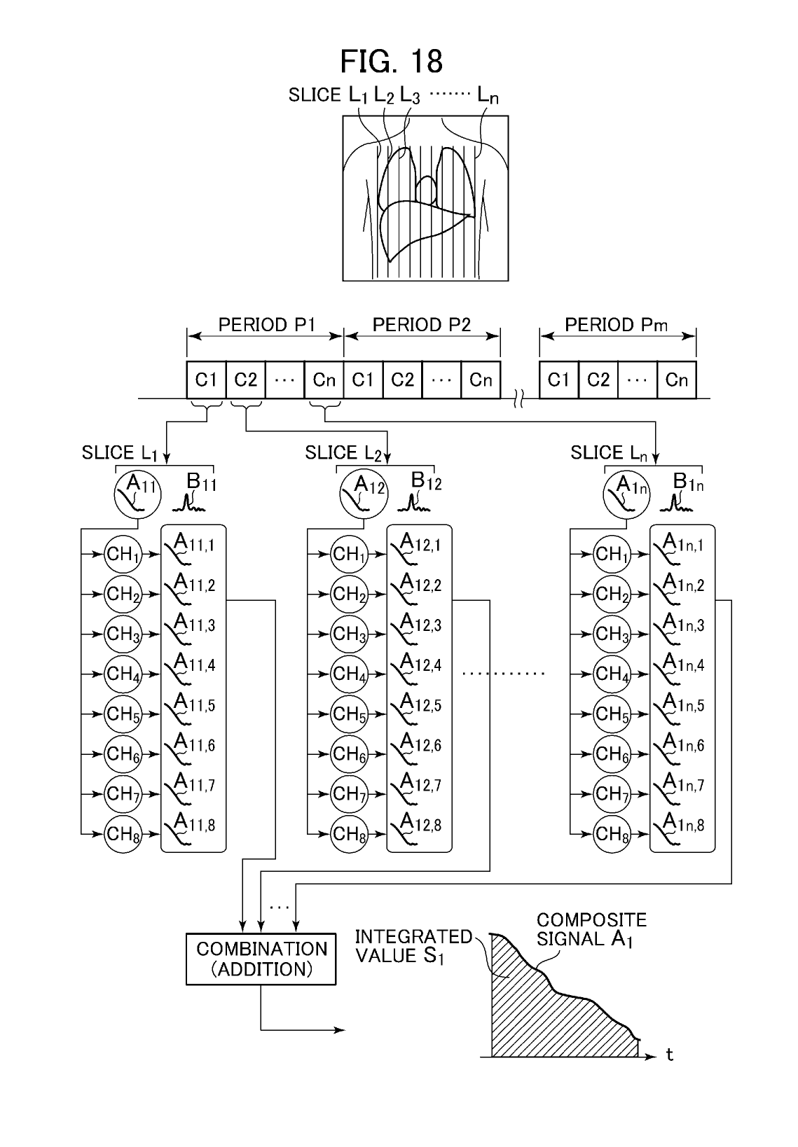

After the composite signal A is obtained, the integrated value of the composite signal A₁ is calculated after the composite signal A₁ is obtained. In FIG. 18, reference numeral “S₁” denotes the integrated value of the composite signal A₁ after the calculation. The integrated value S₁ is used as the signal value of the respiratory signal of the subject in the period P₁.

After the sequence is performed in the period P₁, the process advances to the period P₂.

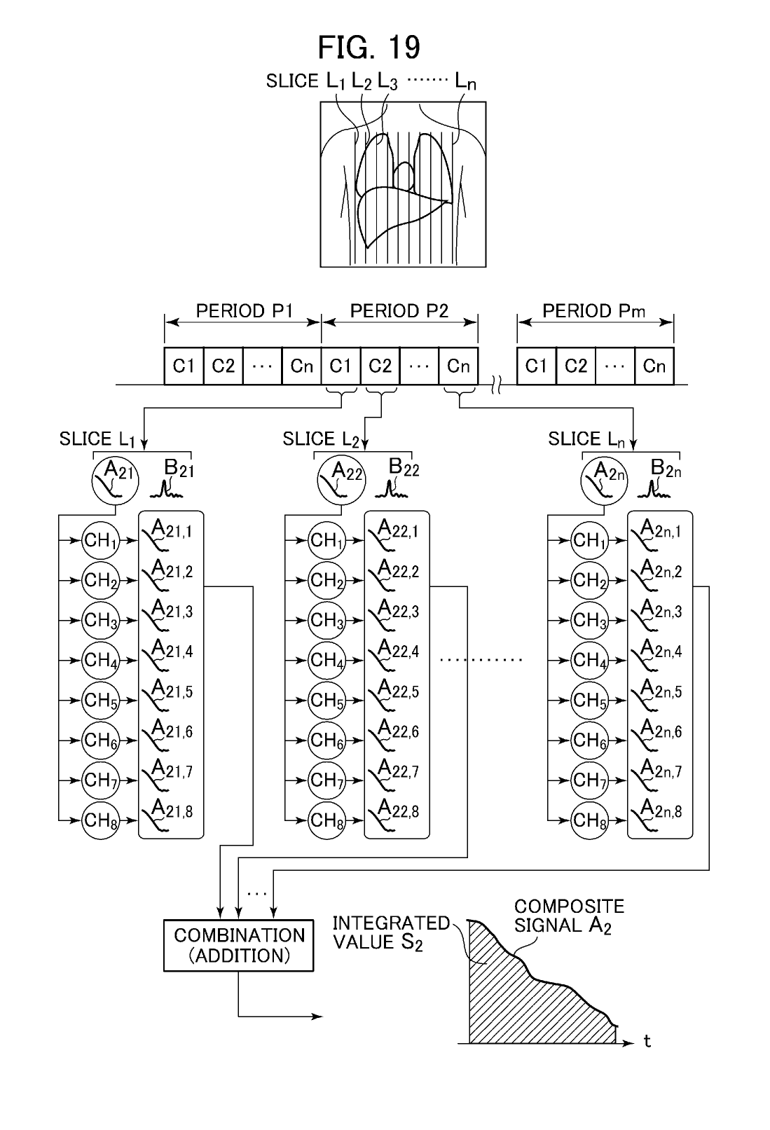

FIG. 19 is an explanatory drawing when the signal value of the respiratory signal is calculated in the period P₂.

The sequences are performed in the period P₂ as in the period 1, combining the signals of the channels. Furthermore, an integrated value S₂ of a composite signal A₂. The integrated value S₂ is used as the signal value of the respiratory signal of the subject.

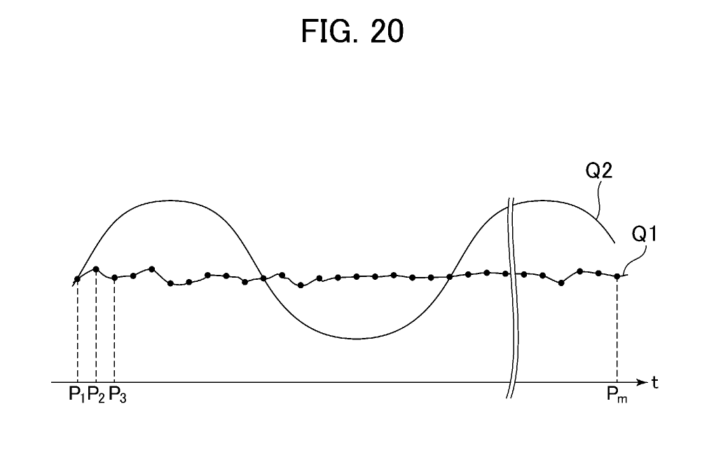

The sequences C1 to Cn are similarly performed in each period to calculate the integrated value of the composite signal. Thus, the signal value of the respiratory signal can be determined in each of the periods (FIG. 20).

FIG. 20 is a schematic diagram showing the signal value of the respiratory signal in each of the periods.

FIG. 20 is a diagram showing a respiratory signal Q1 obtained by the method of FIGS. 14 to 19 and an ideal respiratory signal Q2.

In order to recognize a respiratory condition (exhalation, inhalation, etc.) of the subject, like the ideal respiratory signal Q2, the respiratory signal needs to be changed as largely as possible with the passage of time in response to a respiratory movement of the subject. If the respiratory signal is generated by the method of FIGS. 14 to 19, however, the respiratory signal has a small amplitude, leading to difficulty in obtaining a suitable respiratory signal.

Hence, in order to clarify the reason for the small amplitude of the respiratory signal, the inventor actually scanned the subject using the sequences shown in FIG. 9 and examined a difference between a respiratory signal obtained from the composite signal of all the channels and a respiratory signal obtained from the received signal of one channel. The examination result will be discussed below.

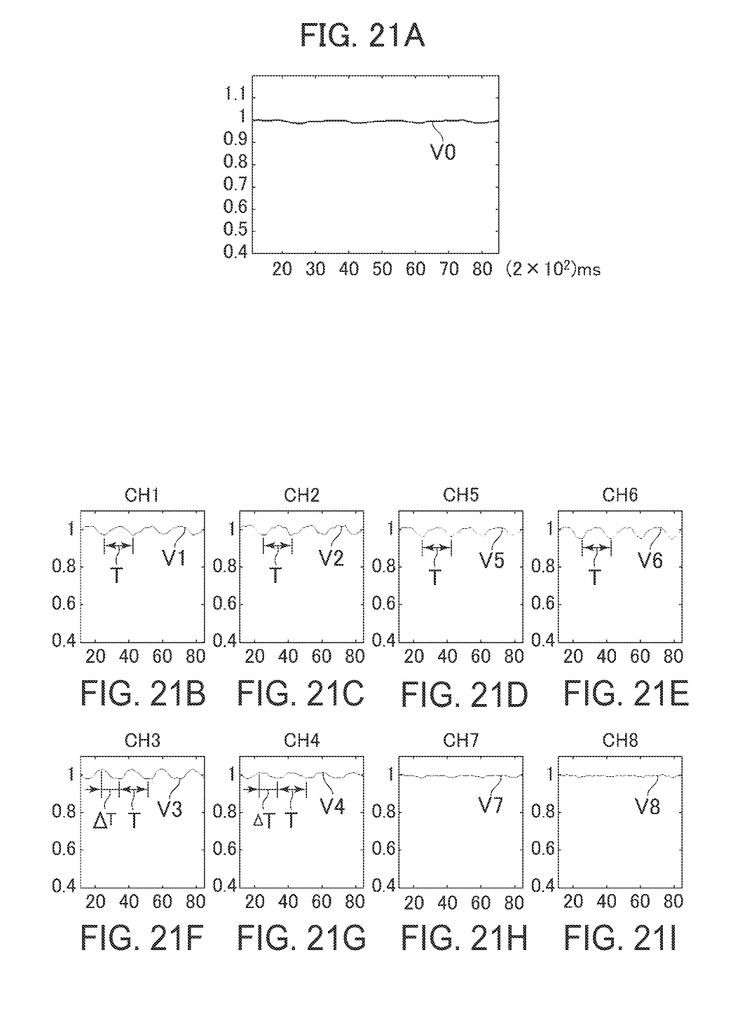

FIGS. 21A and 21B show the respiratory signal.

FIG. 21A shows a respiratory signal V0 obtained from the composite signal of all the channels. FIG. 21A proves that the respiratory signal V0 does not greatly increase.

FIGS. 21B-21I show eight respiratory signals, each being obtained from only one channel. FIGS. 21B-21I will be discussed below.

FIG. 21B shows a respiratory signal V1 obtained only from the received signal of the channel CH1. FIG. 21B proves that the respiratory signal V1 (period T) of the channel CH1 greatly changes in response to a movement of the liver.

FIG. 21C shows a respiratory signal V2 obtained only from the received signal of the channel CH2. Like the respiratory signal V1 of the channel CH1, the respiratory signal V2 of the channel CH2 greatly changes in response to a movement of the liver.

FIG. 21D shows a respiratory signal V3 obtained only from the received signal of the channel CH3. Like the respiratory signal V1 of the channel CH1, the respiratory signal V3 of the channel CH3 greatly changes in response to a movement of the liver. The waveform of the respiratory signal V3 of the channel CH3 is however displaced only by ΔT from that of the respiratory signal V1 of the channel CH1 in the time direction.

FIG. 21E shows a respiratory signal V4 obtained only from the received signal of the channel CH4. Like the respiratory signal V1 of the channel CH1, the respiratory signal V4 of the channel CH4 greatly changes in response to a movement of the liver. The waveform of the respiratory signal V4 of the channel CH4 is however displaced only by ΔT from that of the respiratory signal V1 of the channel CH1 in the time direction.

FIG. 21F shows a respiratory signal V5 obtained only from the received signal of the channel CH5. Like the respiratory signal V1 of the channel CH1, the respiratory signal V5 of the channel CH5 greatly changes in response to a movement of the liver. The waveform of the respiratory signal V5 of the channel CH5 is hardly displaced from that of the respiratory signal V1 of the channel CH1 in the time direction.

FIG. 21G shows a respiratory signal V6 obtained only from the received signal of the channel CH6. Like the respiratory signal V1 of the channel CH1, the respiratory signal V6 of the channel CH6 greatly changes in response to a movement of the liver. The waveform of the respiratory signal V6 of the channel CH6 is hardly displaced from that of the respiratory signal V1 of the channel CH1 in the time direction.

FIG. 21H shows a respiratory signal V7 obtained only from the received signal of the channel CH7. The respiratory signal V7 of the channel CH7 does not greatly vary in amplitude, proving that a movement of the liver is not sufficiently reflected.

FIG. 21I shows a respiratory signal V8 obtained only from the received signal of the channel CH8. The respiratory signal V8 of the channel CH8 does not greatly vary in amplitude, proving that a movement of the liver is not sufficiently reflected.

This proves that the waveform of the included respiratory signal is displaced only by ΔT from that of the respiratory signal V1 of the channel CH1 in the time direction. For example, the waveform of the respiratory signal V3 of the channel CH3 is displaced only by ΔT from that of the respiratory signal V1 of the channel CH1 in the time direction. The reason why the waveform of the respiratory signal is displaced in the time direction will be examined below.

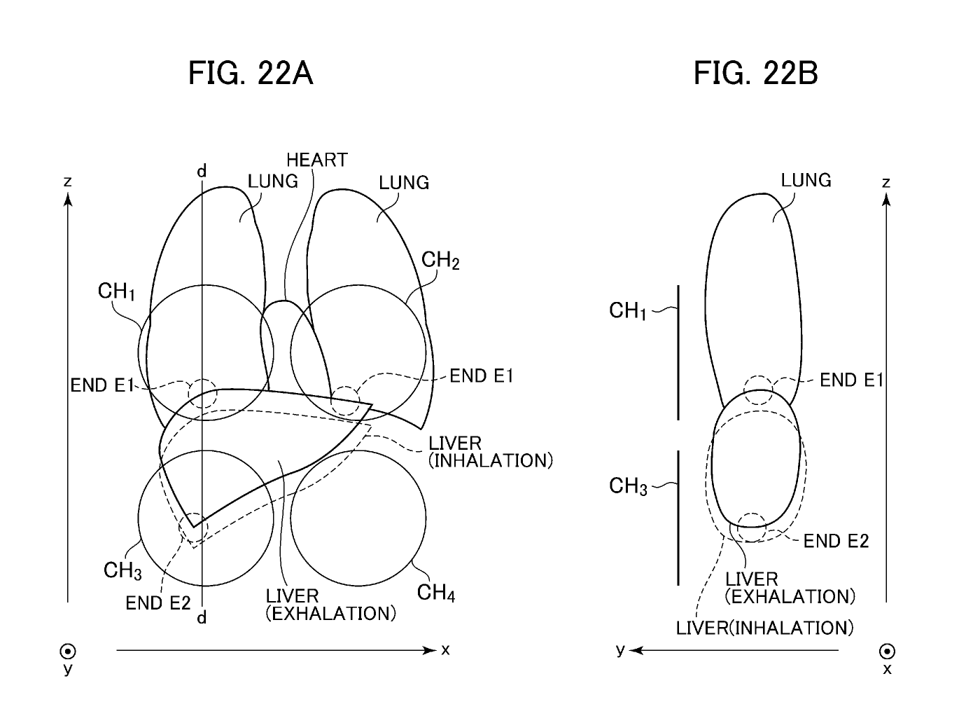

FIGS. 22A and 22B are schematic diagrams showing the positional relationship between the channels CH1 and CH3 and a liver. In FIGS. 22A and 22B, the liver during exhalation is indicated by a solid line, whereas the liver during inhalation is indicated by a broken line.

When the subject exhales, the end E1 of the liver moves in the z direction, bringing the liver close to the channel CH1. Thus, the signal value of the received signal of the channel CH1 is increased by the influence of the liver, whereas the liver is separated from the channel CH3 and thus reduces the signal value of the received signal of the channel CH3.

When the subject inhales, the end E1 of the liver moves in the −z direction and thus the liver is separated from the channel CH1. This reduces the signal value of the received signal of the channel CH1. Meanwhile, the liver approaches the channel CH3 and thus increases the signal value of the received signal of the channel CH3. This reverses a fluctuation of the received signal of the channel CH1 and a fluctuation of the received signal of the channel CH3.

Since the fluctuations of the received signals are reversed, the waveform of the respiratory signal V3 obtained from the received signal of the channel CH3 is displaced only by ΔT in the time direction from that of the respiratory signal V1 obtained from the received signal of the channel CH1. Hence, the respiratory signals V1 and V3 are added so as to cancel each other.

FIGS. 21B-21I show that the respiratory signals V7 and V8 of the channels CH7 and CH8 do not greatly vary in amplitude. This is because the channels CH7 and CH8 are farther from the liver than the other channels and thus a movement of the liver does not considerably change a signal value.

Thus, the channels CH1 to CH8 include channels where the signals cancel each other and channels that do not sufficiently reflect a movement of the liver. Thus, if the received signals of all the channels are combined, the respiratory signals do not greatly vary in amplitude.

FIGS. 21B-21I prove that some of the channels CH1 to CH8 hardly displace the waveforms of the respiratory signals in the time direction. Specifically, the respiratory signals V1, V2, V5, and V6 of the channels CH1, CH2, CH5, and CH6 are hardly displaced in the time direction. The channels CH1, CH2, CH5, and CH6 located near the end E1 of the liver simultaneously fluctuate in signal value in response to a movement of the liver, hardly displacing the waveforms of the respiratory signals in the time direction. Thus, the respiratory signals greatly changing in response to a respiratory movement of the subject can be obtained by combining only the received signals of the channels CH1, CH2, CH5, and CH6. In the first embodiment, among the channels CH1 to CH8, only the received signals of the channel CH1, CH2, CH5, and CH6 disposed near the end E1 of the liver are used to generate the respiratory signals. A method of generating the respiratory signals according to the first embodiment will be described below.

In the first embodiment, a database containing information on the channels of the coil is stored in the memory 9 (FIG. 1). FIG. 23 is a schematic diagram showing data registered in the database.

Items registered in the database are: a indicating the coil, b indicating the channels of the coil, and c indicating whether the channels are located or not, beside the lungs, near the end E1 of the liver. Circles in the item c indicate that the channels are located near the end E1 of the liver. In this case, the channels CH1, CH2, CH5, and CH6 are registered as channels located near the end E1 of the liver.

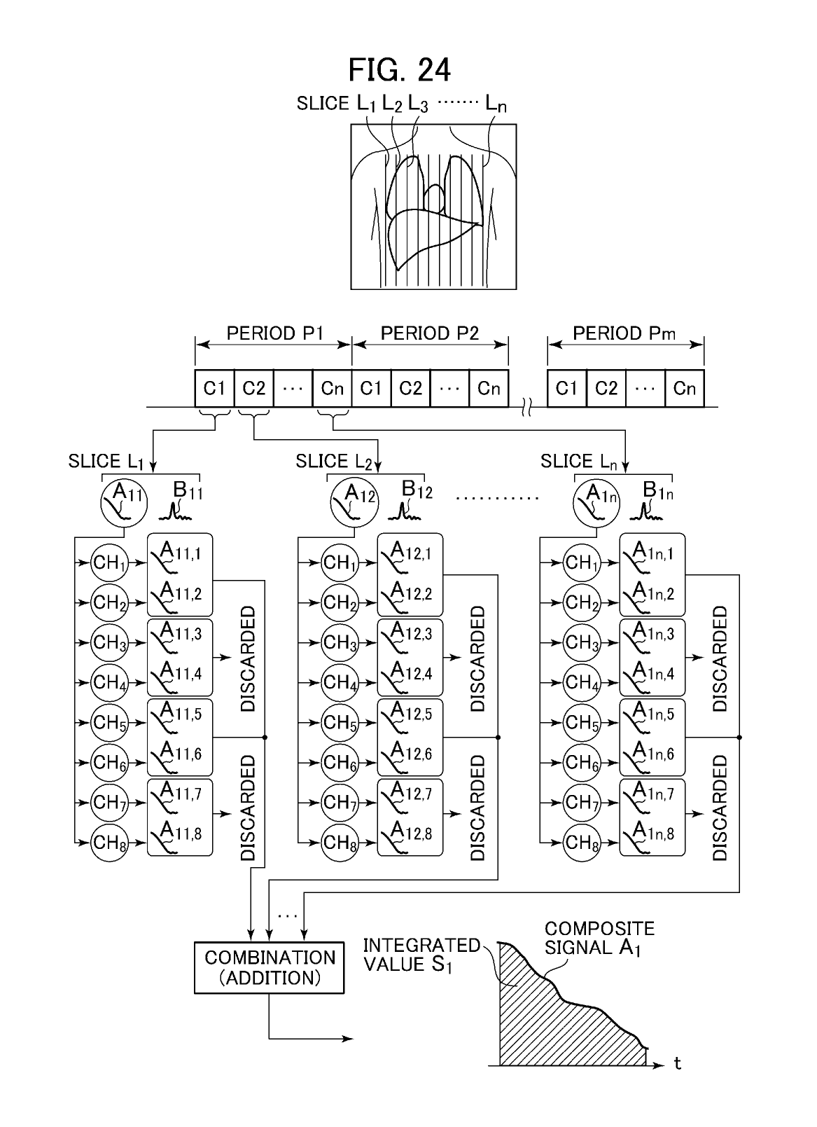

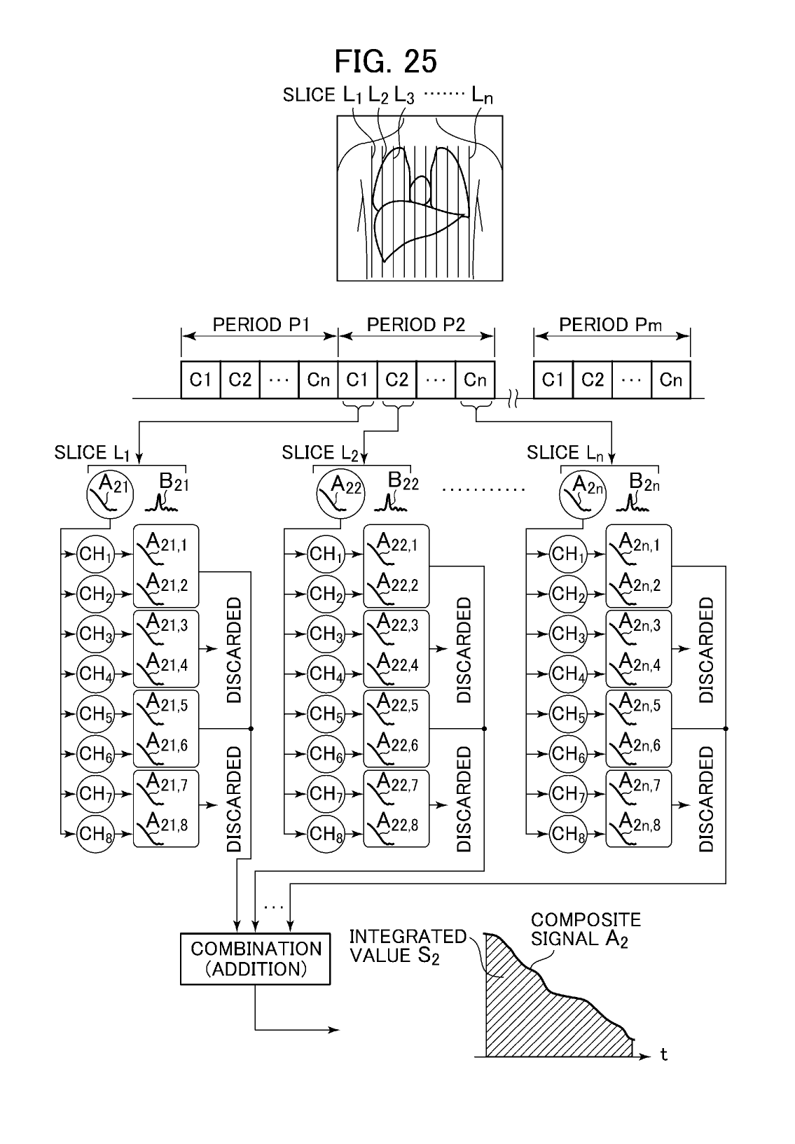

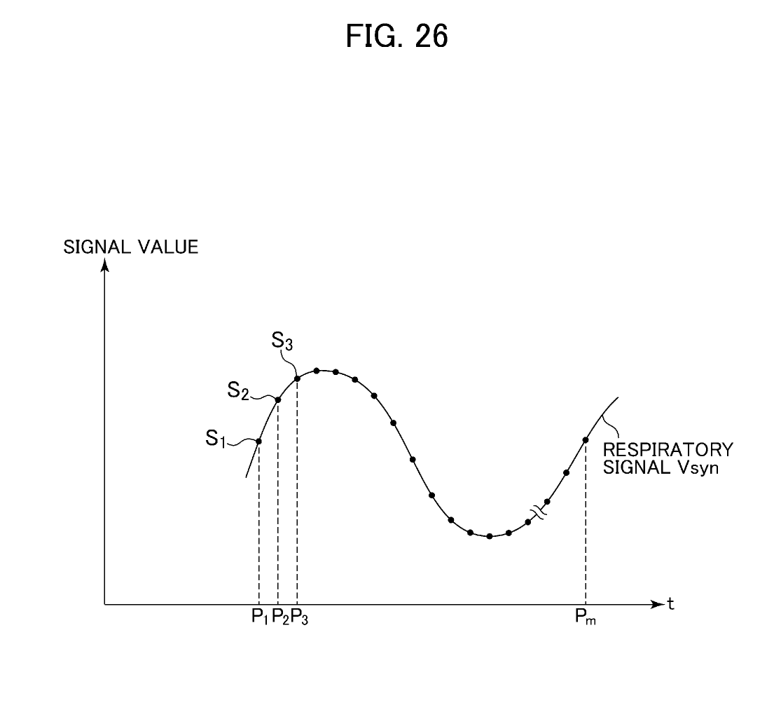

In the first embodiment, the respiratory signals are generated based on the database of FIG. 23. Referring to FIGS. 24 and 25, the steps of generating the respiratory signals using the database will be described below.

First, as shown in FIG. 24, the sequence C1 is performed in the period P₁. The DC signal A₁₁ and the imaging signal B₁₁ are collected from the slice L1 by performing the sequence C1.

Since the coil 4 has the channels CH1 to CH8, the DC signal A₁₁ is received by each of the channels CH1 to CH8. The channels CH1 to CH8 respectively output the signals A_{11,1} to A_{11,8} in response to the received DC signal A₁₁.

After the execution of the sequence C1, the sequence C2 is performed. The DC signal A₁₂ and the imaging signal B₁₂ are collected from the slice L2 by performing the sequence C2.

Like the DC signal A₁₁, the DC signal A₁₂ is received by each of the channels CH1 to CH8. The channels CH1 to CH8 respectively output the signals A_{12,1} to A_{12,8} in response to the received DC signal A₁₂.

After that, the sequences for collecting the DC signals and the imaging signals from the slices L3 to Ln are performed in a similar manner. At the end of the period P₁, the sequence Cn for collecting data on the slice Ln is performed. The DC signal A₁ₙ and the imaging signal B₁ₙ are collected from the slice Ln by performing the sequence Cn.

The DC signal A₁ₙ is received by each of the channels CH1 to CH8. The channels CH1 to CH8 respectively output the signals A_{1n,1} to A_{1n,8} in response to the received DC signal A₁ₙ.

After the sequences C1 to Cn are performed in the period P1, the respiratory signal is generated as follows:

First, the channel selecting unit 82 (FIG. 5) refers to the database (FIG. 23). The channel selecting unit 82 then selects the channels CH1, CH2, CH5, and CH6 that are registered as channels located near the end E1 of the liver, based on the information on the item c of the database.

Subsequently, the respiratory signal generating unit 83 (FIG. 5) abandons the output signals of the channels CH3, CH4, CH7, and CH8 unselected out of the channels CH1 to CH8, and combines (adds) only the output signals of the selected channels CH1, CH2, CH5, and CH6. The composite signal A1 is obtained thus.

After the composite signal A1 is obtained, the respiratory signal generating unit 83 calculates the integrated value S₁ of the composite signal A₁. The integrated value S₁ is used as the signal value of the respiratory signal of the subject in the period P₁. After the sequence is performed in the period P₁, the process advances to the period P₂.

FIG. 25 is an explanatory drawing when the respiratory signal is calculated in the period P₂. The sequences C1 to Cn are performed in the period P₂ as in the period 1. The respiratory signal generating unit 83 abandons the output signals of the channels CH3, CH4, CH7, and CH8 and combines (adds) only the output signals of the selected channels CH1, CH2, CH5, and CH6. The composite signal A₂ is generated thus. The respiratory signal generating unit 83 then determines the integrated value S₂ of the composite signal A₂. The integrated value S₂ is used as the signal value of the respiratory signal of the subject in the period P₂.

Subsequently, the sequences C1 to Cn are performed in each of the periods. The respiratory signal generating unit 83 abandons the output signals of the channels CH3, CH4, CH7, and CH8 and combines (adds) only the output signals of the selected channels CH1, CH2, CH5, and CH6. After that, the integrated value of the composite signal is calculated, thereby obtaining the respiratory signal in each period (FIG. 26).

FIG. 26 is a schematic diagram showing the respiratory signal obtained by the method of the first embodiment.

In the first embodiment, only the output signals of the channels CH1, CH2, CH5, and CH6 located near the end E1 of the liver are combined (added). Since the output signals of the channels CH1, CH2, CH5, and CH6 fluctuate at the same time, a respiratory signal Vsyn greatly fluctuating in response to a respiratory movement of the subject can be obtained by combining only the output signals of the channels.

Moreover, the liver is moved by a respiratory movement and thus the reconstruction of an image using only the imaging signals collected in the periods P1 to Pm may cause a body motion artifact on the image. Thus, in order to reduce body motion artifacts in the first embodiment, it is decided whether the imaging signal should be accepted as a signal used for reconstructing an image or the acceptance of the imaging signal should be rejected, based on the respiratory signal Vsyn. The decision method will be discussed below.

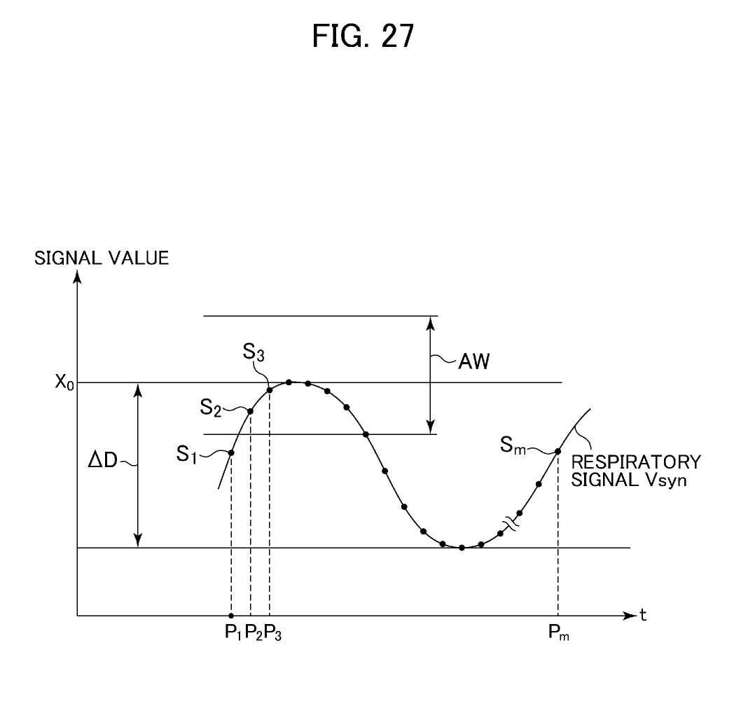

FIG. 27 is an explanatory drawing showing the method of deciding the acceptance and rejection of the imaging signal.

First, the decision unit 84 (FIG. 5) determines a signal value x0 corresponding to the position of the end of the exhalation of the subject. The signal value x0 at the end of exhalation can be determined with reference to, for example, the peak value of the respiratory signal. Subsequently, a difference ΔD between the maximum value and the minimum value of the respiratory signal is determined. A range AW of x % (e.g., x=20) of the difference ΔD is set around the signal value x0 at the end of exhalation. The range AW set thus is determined as an allowable range AW for accepting the imaging signal B. If the respiratory signal is included in the allowable range AW, the decision unit 84 decides that the imaging signal should be accepted as a signal used for reconstructing an image. If the respiratory signal is not included in the allowable range AW, the decision unit 84 decides that the imaging signal should be rejected as a signal used for reconstructing an image. In FIG. 27, the signal value (integrated value) S₁ of the period P₁ is not included in the allowable range AW and thus the imaging signals B₁₁ to B₁ₙ (FIG. 24) collected in the period P₁ are rejected. However, the signal value (integrated value) S₂ of the period P₂ is included in the allowable range AW and thus the imaging signals and thus it is decided that the imaging signals B₂₁ to B₂ₙ (FIG. 25) collected in the period P₂ should be accepted. After that, it is decided whether the imaging signal should be accepted or rejected, depending on whether or not the respiratory signal in each period is included in the allowable range AW.

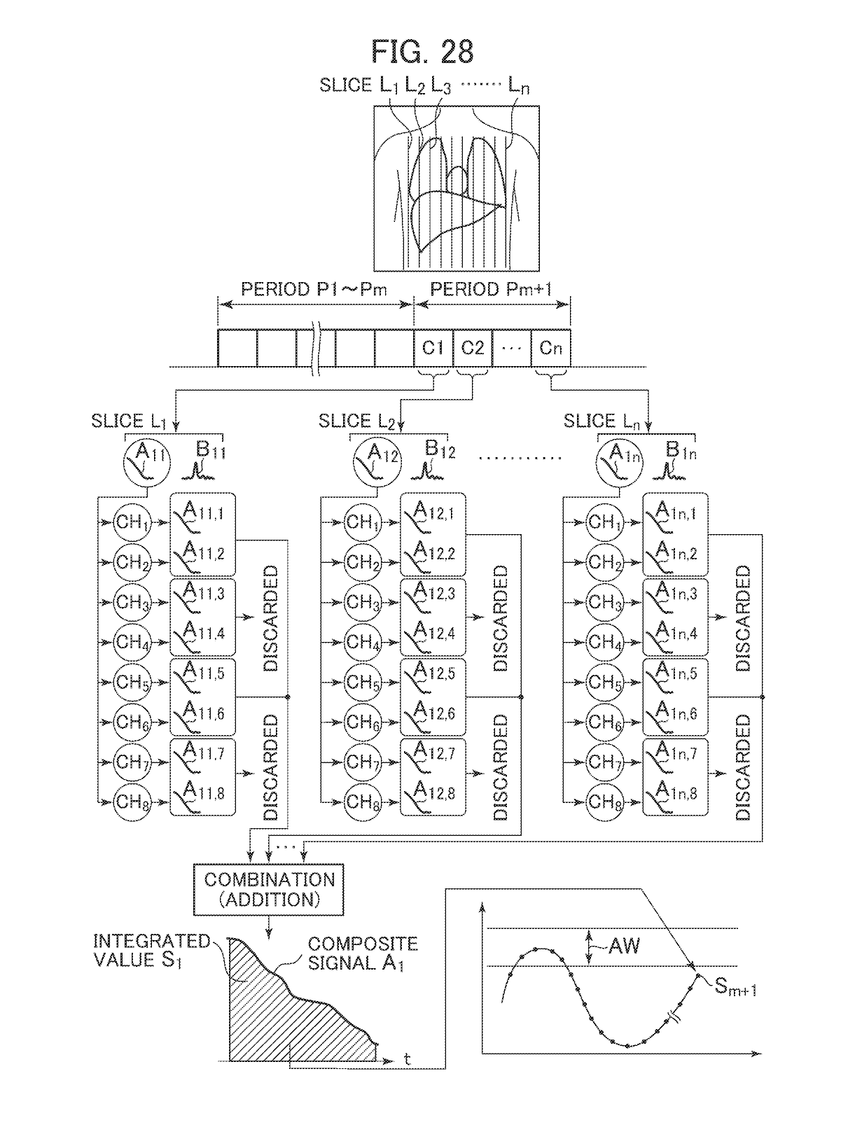

Out of the imaging signals collected in the periods P₁ to Pₘ, the imaging signal rejected as a signal used for reconstructing an image is recollected after the period Pm. For example, the imaging signal B₁₁ to B₁ₙ (FIG. 24) collected in the period P₁ are rejected as signals used for reconstructing an image, and thus the imaging signal B₁₁ to B₁ₙ are recollected (FIG. 28).

FIG. 28 is an explanatory drawing when the imaging signals B₁₁ to B₁ₙ are recollected.

In a period P_{m+1,} the sequences C1 to Cn for collecting the imaging signals B₁₁ to B₁ₙ are performed. The DC signals A₁₁ to A₁ₙ and the imaging signals B₁₁ to B₁ₙ are recollected by performing the sequences C1 to Cn.

The DC signals A₁₁ to A₁ₙ and the imaging signals B₁₁ to B₁ₙ are received by each of the channels CH1 to CH8. For convenience of explanation, FIG. 28 only shows a state in which the DC signals A₁₁ to A₁ₙ are received by each of the channels CH1 to CH8. The channels CH1 to CH4 output the signals A_{11,1} to A_{11,8}, respectively.

The respiratory signal generating unit 83 generates the composite signal of the output signals of the channels CH1, CH2, CH5, and CH6 and calculates an integrated value Sₘ₊₁ of a composite signal Aₘ₊₁. Thus, the respiratory signal Sₘ₊₁ in the period Pₘ₊₁ can be obtained.

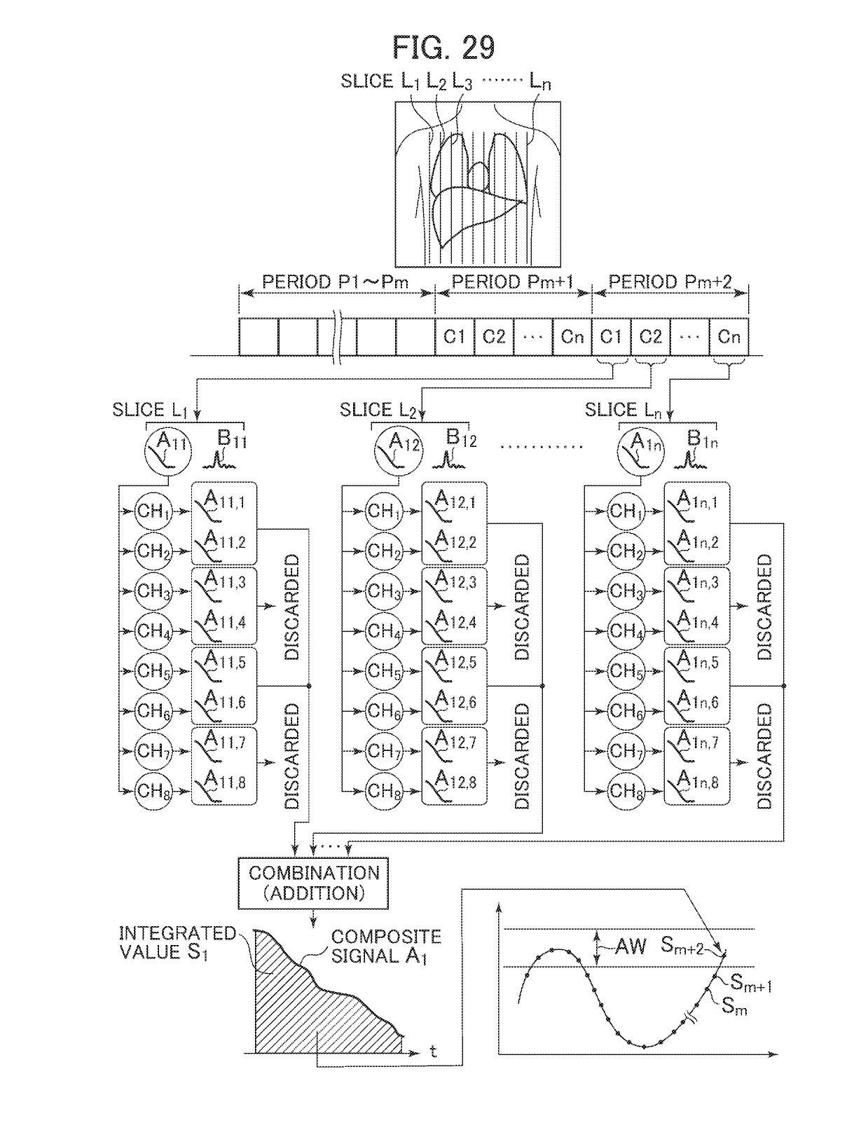

Subsequently, the decision unit 84 decides whether or not the respiratory signal Sₘ₊₁ is included in the allowable range AW. In FIG. 28, the respiratory signal Sₘ₊₁ is not included in the allowable range AW and thus the imaging signals B₁₁ to B₁ₙ collected in the period Pₘ₊₁ cannot be accepted as data for reconstructing an image. Thus, the imaging signals B₁₁ to B₁ₙ are rejected. In this case, also in the subsequent period Pₘ₊₂, the sequences C1 to Cn for recollecting the imaging signals B₁₁ to B₁ₙ are performed (FIG. 29).

FIG. 29 is an explanatory drawing when the sequences C1 to Cn are performed in the period Pₘ₊₂.

In the period Pₘ₊₂, the sequences C1 to Cn for recollecting the imaging signals B₁₁ to B₁ₙ are performed as in the period Pₘ₊₁. The DC signals A₁₁ to A₁ₙ and the imaging signals B₁₁ to B₁ₙ are recollected by performing the sequences C1 to Cn.

The DC signals A₁₁ to A₁ₙ and the imaging signals B₁₁ to B₁ₙ are received by each of the channels CH1 to CH8. For convenience of explanation, FIG. 29 only shows a state in which the DC signals A₁₁ to A₁ₙ are received by each of the channels CH1 to CH8. The channels CH1 to CH8 output the signals A_{11,1} to A_{11,8}, respectively.

The respiratory signal generating unit 83 generates the composite signal of the output signals of the channels CH1, CH2, CH5, and CH6 and calculates an integrated value S_{m +2} of a composite signal Aₘ₊₂. Thus, the respiratory signal Sₘ₊₂ in the period Pₘ₊₂ can be obtained.

Subsequently, the decision unit 84 decides whether or not the respiratory signal Sₘ₊₂ is included in the allowable range AW. In FIG. 29, the respiratory signal Sₘ₊₂ is included in the allowable range AW and thus it is decided that the imaging signals B₁₁ to B₁ₙ collected in the period Pₘ₊₂ should be accepted as data for reconstructing an image.

Also in the case of the recollection of other rejected imaging signals, the sequences are repeatedly performed in a similar manner until the respiratory signal is included in the allowable range AW. Thus, the imaging signal of ky=−32 to 32, which is collected when the respiratory signal is included in the allowable range AW, can be obtained as data for reconstructing an image.

After the rejected imaging signal is recollected thus, an image is reconstructed.

In the first embodiment, the DC signals received by the channels located near the end E1 of the liver are combined, thereby obtaining the respiratory signal Vsyn greatly fluctuating in response to a respiratory movement of the subject. This can roughly specify the range AW of the respiratory signal at the end of the exhalation of the subject. Moreover, in the first embodiment, if the respiratory signal is not included in the range AW, the imaging signals are recollected until the respiratory signal is included in the range AW. This can obtain an image with reduced body motion artifacts.

In the first embodiment, the four channels CH1, CH2, CH5, and CH6 are registered as channels located near the end E1 of the liver. However, instead of registration of all the four channels CH1, CH2, CH5, and CH6, only one, two, or three of the four channels CH1, CH2, CH5, and CH6 may be registered. As described above, with reference to FIG. 21, the respiratory signal can be obtained with a sufficiently reflected movement of the liver. Thus, the respiratory signal with a sufficiently reflected movement of the liver can be obtained by registering at least one of the four channels CH1, CH2, CH5, and CH6.

Instead of the channels CH1, CH2, CH5, and CH6 located on the end E1 of the liver, for example, the channel CH3 located near the end E2 (FIG. 3) of the liver may be registered. As described above, with reference to FIG. 21, the waveform of the respiratory signal obtained from the channel CH3 is displaced only by ΔT in the time direction from that of the respiratory signal obtained from the channel CH1. However, a movement of the liver is sufficiently reflected. Thus, even if the channel CH3 is registered instead of the channels CH1, CH2, CH5, and CH6, the respiratory signal can be obtained with a sufficiently reflected movement of the liver.

In the first embodiment, the slice setting unit 81 sets the slice based on information inputted from the operation unit 10 by the operator. However, the slice setting unit 81 may automatically set the slice based on the image D.

### (2) Second Embodiment

In the first embodiment, the channels CH1, CH2, CH5, and CH6 disposed near the end E1 of the liver are registered in the database, and then the channels CH1, CH2, CH5, and CH6 are selected from the channels CH1 to CH8 with reference to the information of the database. In the example of a second embodiment, channels CH1, CH2, CH5, and CH6 disposed near an end E1 of a liver are selected from the channels CH1 to CH8 without being registered in a database. The hardware configuration of an MR apparatus is identical to that of the first embodiment.

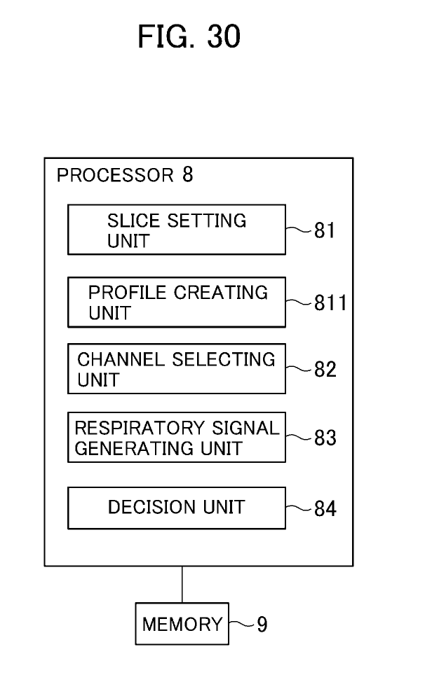

FIG. 30 is an explanatory drawing of processing performed by a processor according to the second embodiment.

A processor 8 reads programs stored in a memory 9 and realizes functions from a slice setting unit 81 to a decision unit 84, and so on.

The slice setting unit 81 sets slices based on information inputted from an operation unit 10.

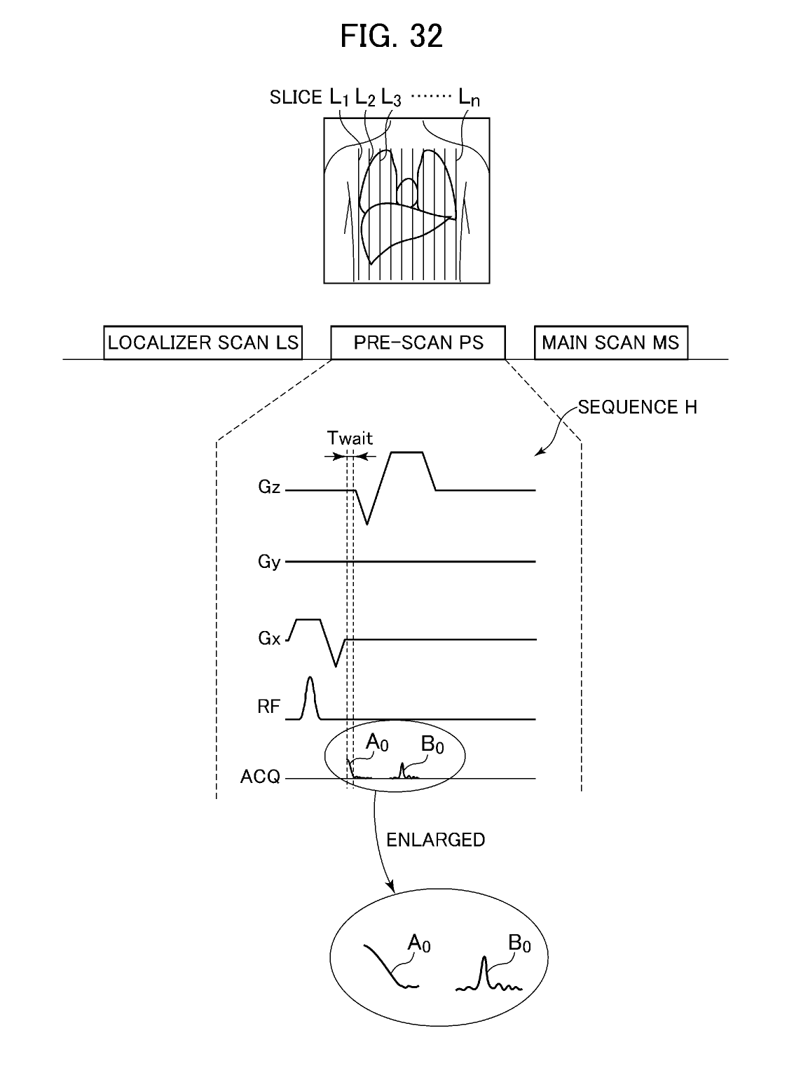

A profile creating unit 811 creates a profile indicating the relationship between positions and signal values in the z direction of an imaged part, based on an MR signal collected by a pre-scan PS (FIG. 32), which will be described later.

The channel selecting unit 82 selects the channels disposed near the end E1 (FIGS. 3A and 3B) of the liver out of the channels CH1 to CH8 included in a coil 4, based on the profile created by the profile creating unit 811.

The respiratory signal generating unit 83 generates a respiratory signal based on the output signal of the channel selected by the channel selecting unit 82.

The decision unit 84 decides whether an imaging signal should be accepted or not as an image reconstruction signal.

The processor 8 performs predetermined programs so as to function as these units.

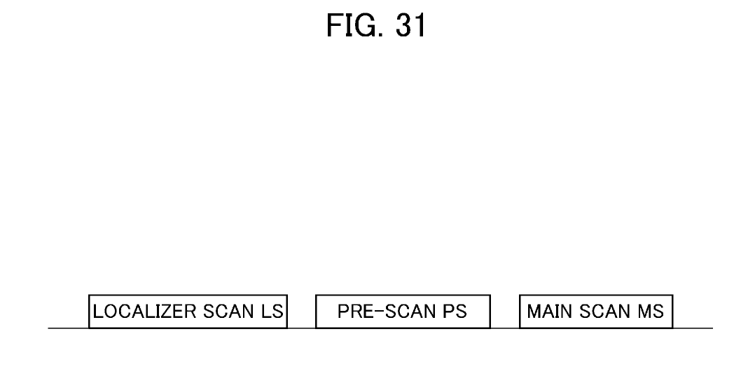

FIG. 31 is an explanatory drawing of a scan performed in the second embodiment. In the second embodiment, a localizer scan LS, a pre-scan PS, and a main scan MS are performed. The second embodiment is similar to the first embodiment in that the localizer scan LS and the main scan MS are performed, while the second embodiment is different from the first embodiment in that the pre-scan PS is performed between the localizer scan LS and the main scan MS.

FIG. 32 is an explanatory drawing of the pre-scan PS.

FIG. 32 shows a sequence H performed in the pre-scan PS. The sequence H is identical to the pulse sequence of FIG. 9 except that a phase encoding gradient pulse is not applied in a Gy direction.

The pre-scan PS is a scan performed for selecting the channels CH1, CH2, CH5, and CH6 disposed near the end E1 of the liver out of the channels CH1 to CH8. The pre-scan PS will be specifically described later.

An operation flow of the MR apparatus in the execution of the localizer scan LS, the pre-scan PS, and the main scan MS in the second embodiment will be described below.

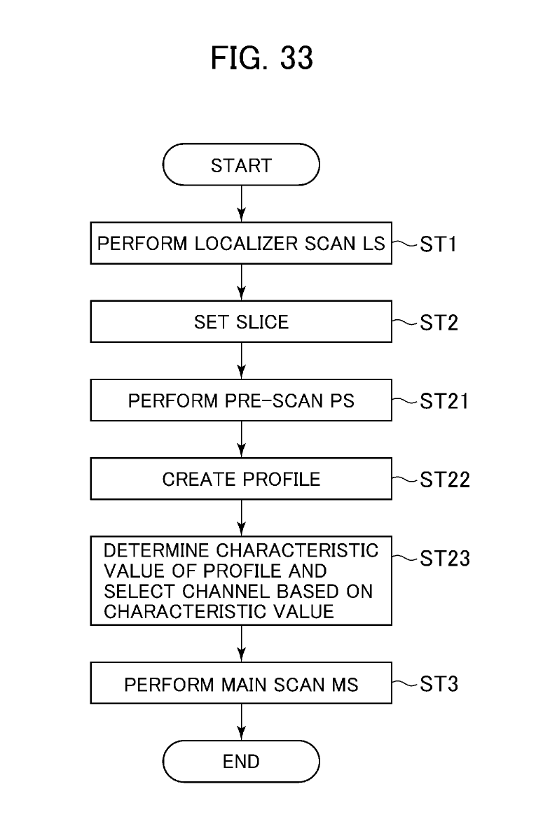

FIG. 33 is a diagram showing the operation flow of the MR apparatus according to the second embodiment.

Steps ST1 and ST2 are similar to those of the first embodiment and thus the detailed explanation thereof is omitted. In step ST2, slices L1 to Ln (FIG. 8) are set and then the process advances to step ST21.

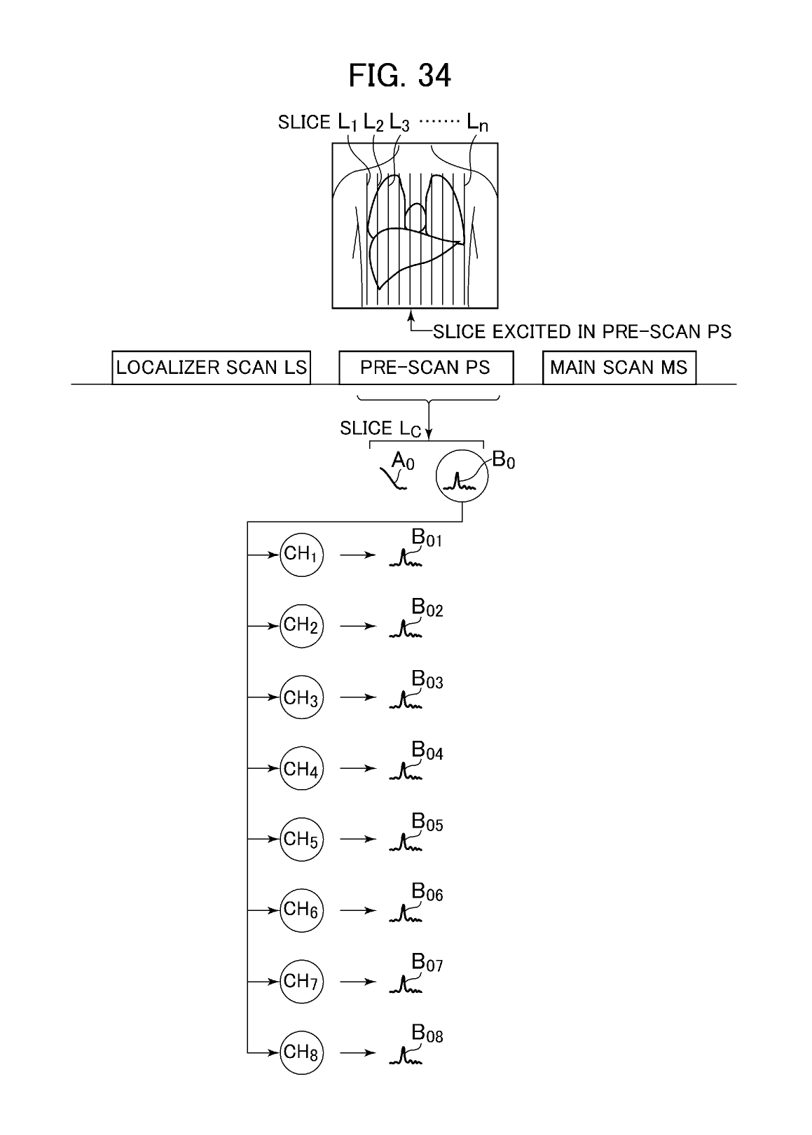

In step ST21, the pre-scan PS is performed. The pre-scan PS is a scan performed for selecting the channels CH1, CH2, CH5, and CH6 disposed near the end E1 of the liver out of the channels CH1 to CH8. The pre-scan PS will be described below (FIG. 34).

FIG. 34 is an explanatory drawing of the pre-scan PS.

In the pre-scan PS, only one of the slices L1 to Ln is excited, and then a DC signal A₀ and an imaging signal B₀ are collected from the excited slice. In the second embodiment, a central slice Lc of the slices L1 to Ln is excited. This collects the DC signal A₀ and the imaging signal B₀ from the slice Lc.

The DC signal A₀ and the imaging signal B₀ are collected from the slice Lc by performing the sequence H. Moreover, the DC signal A₀ and the imaging signal B₀ are received by each of the channels CH1 to CH8. For convenience of explanation, FIG. 34 only shows the DC signal A₀ received by each of the channels CH1 to CH8. Of the DC signal A₀ and the imaging signal B₀, the imaging signal B₀ is used for selecting the channels while the DC signal A₀ is not used for selecting the channels.

The channels CH1 to CH8 respectively output signals B01 to B08 in response to the imaging signal B0 received by the channels CH1 to CH8.

After the pre-scan PS is performed, the process advances to step ST22.

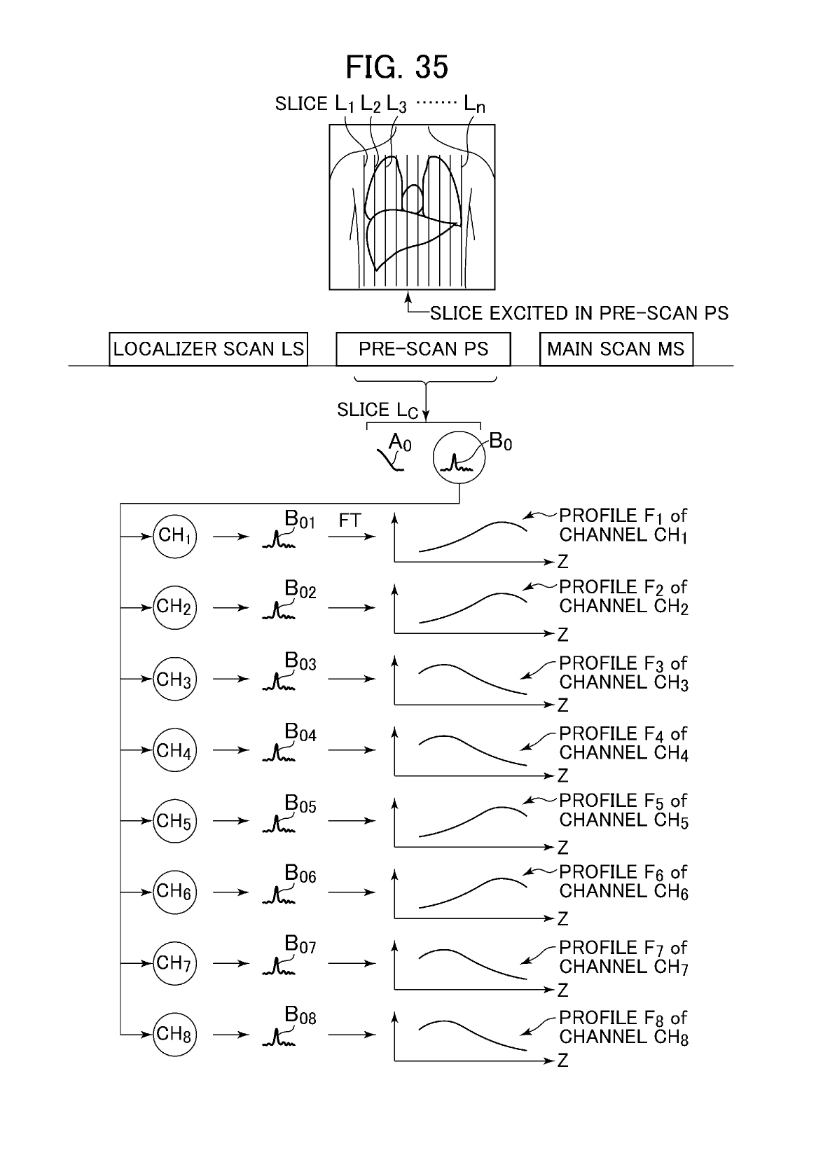

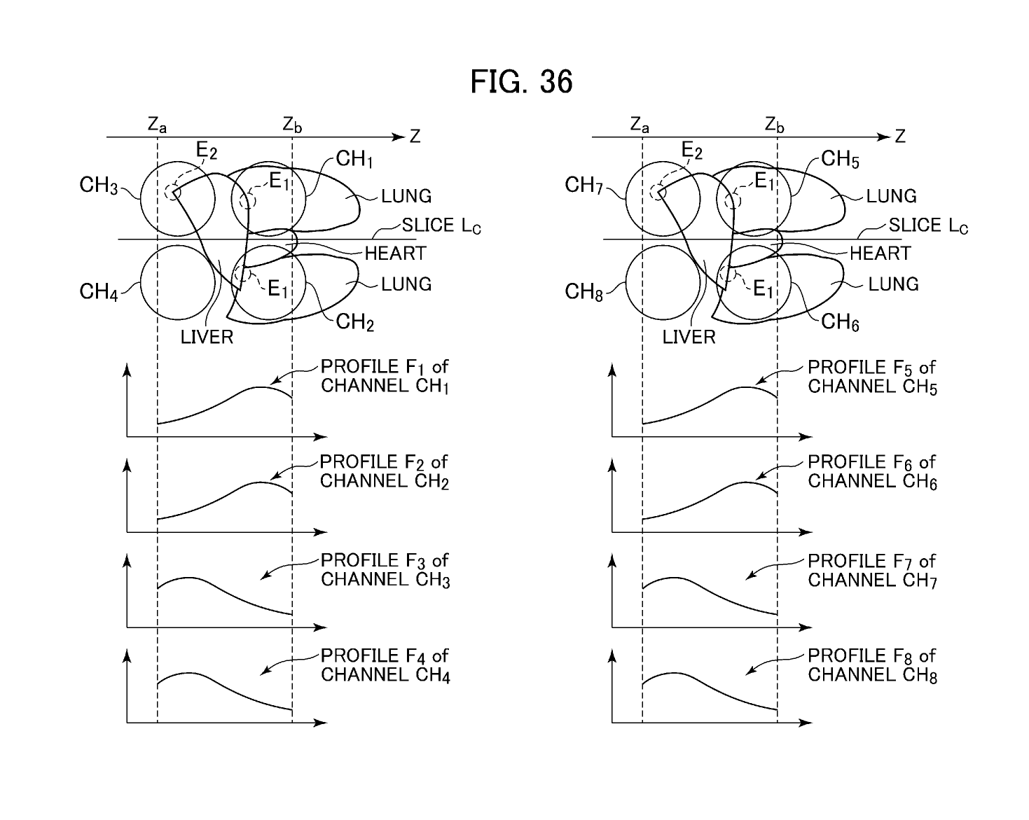

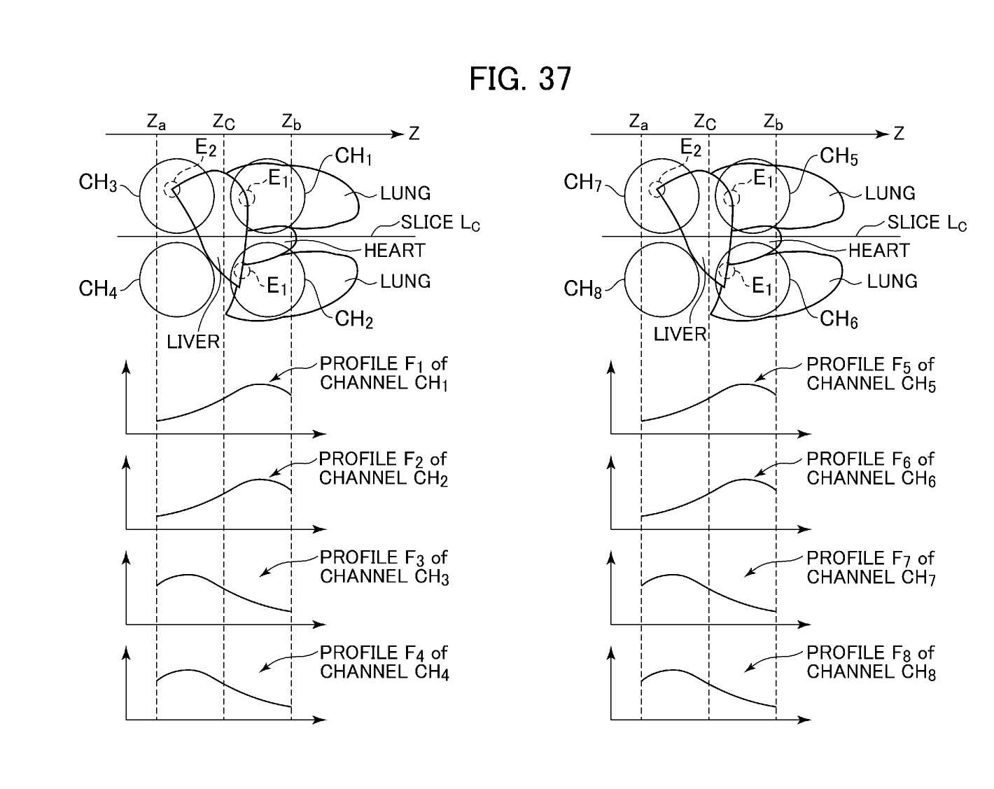

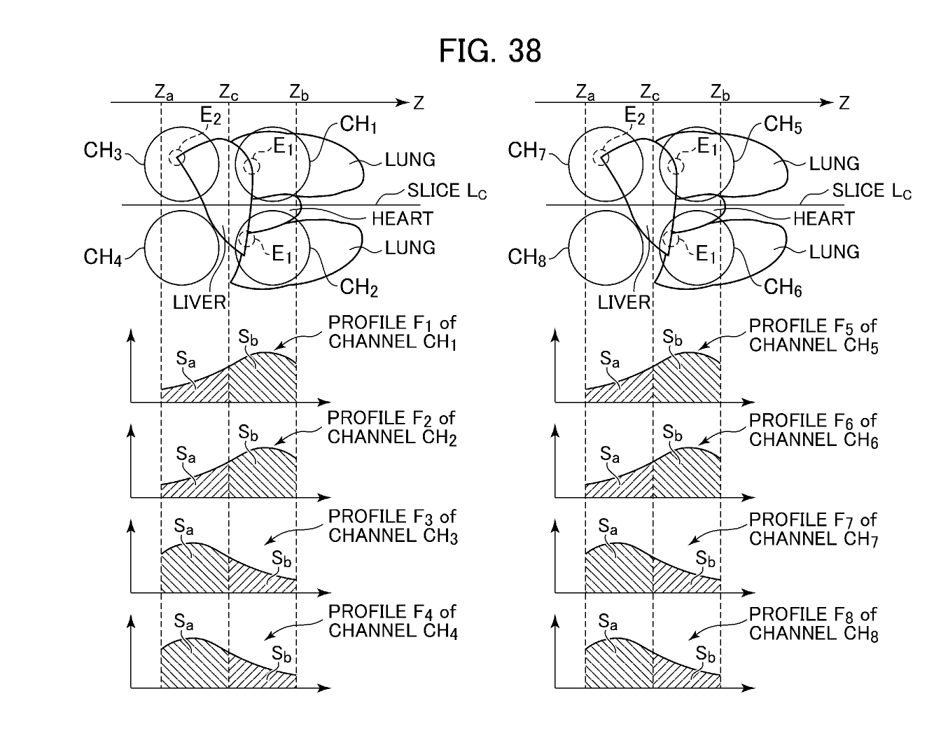

In step ST22, the profile creating unit 811 (FIG. 30) performs Fourier transformation (FT) on the output signals B₀₁ to B₀₈ of the channels CH1 to CH8 in the z direction. Thus, as shown in FIG. 35, profiles (F1 to F8) indicating the relationship between positions in the z direction and signal values can be created for each of the channels. FIG. 36 is a schematic diagram showing the ranges of the profiles F1 to F8 in the z direction. The left side of FIG. 36 shows the range of the profiles F1 to F4 in the z direction, whereas the right side of FIG. 36 shows the range of the profiles F5 to F8 in the z direction.

The ranges of the profiles F1 to F8 are denoted as reference characters “za” and “zb”. za is located near an end E2 of the liver while zb is located so as to cross lungs.

After the profiles F1 to F8 are created, the process advances to step ST23.

In step ST23, the channel selecting unit 82 (FIG. 30) determines characteristic values indicating the characteristics of the profiles F1 to F8, and then selects, from the channels CH1 to CH8, the channel to be disposed near the end E1 of the liver based on the characteristic values. In the following explanation, a method of determining the characteristic values of the profiles CH1 to CH8 is followed by a method of selecting the channels based on the characteristic values.

FIGS. 37 to 39 are explanatory drawings showing the method of determining the characteristic values of the profiles CH1 to CH8.

The channel selecting unit 82 first specifies a center position zc that divides the range za to zb of the profiles F1 to F8 in the z direction. FIG. 37 is a diagram showing the center position zc. After the center position zc is specified, the channel selecting unit 82 calculates an integrated value Sa in a section za-zc and an integrated value Sb in a section zc-zb for each of the profiles. FIG. 38 is a diagram showing the integrated values Sa and Sb calculated for each of the profiles.

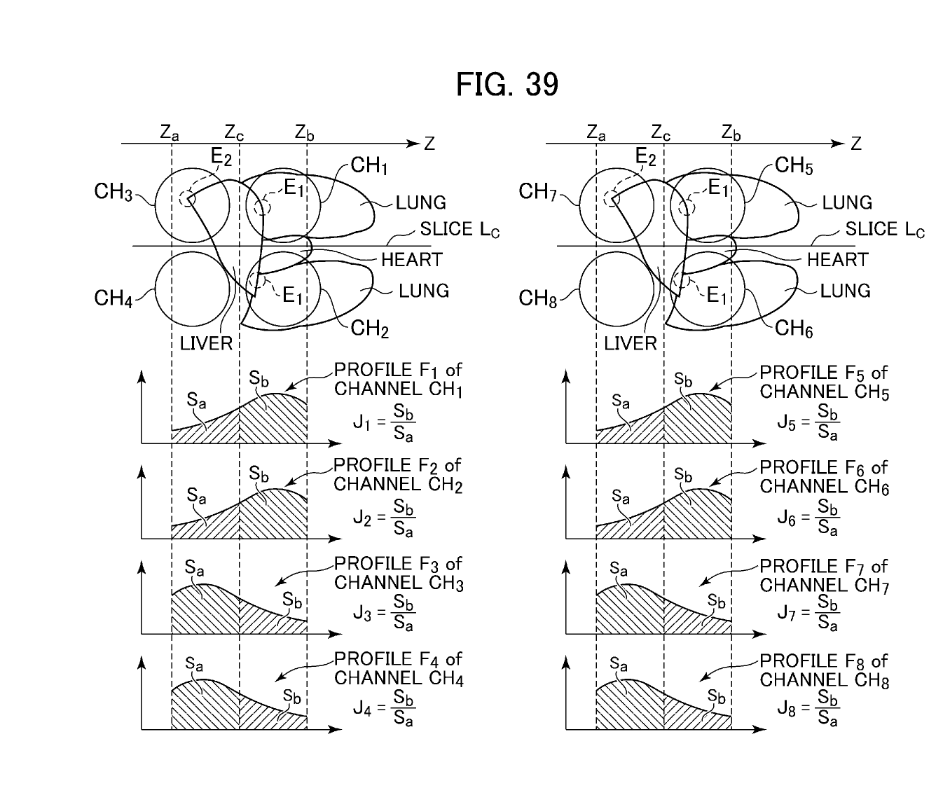

After the integrated values Sa and Sb are calculated, the channel selecting unit 82 calculates the ratio between the integrated values Sb and Sa for each of the profiles. FIG. 39 is a diagram showing the calculated ratio between the integrated values for each of the profiles. In FIG. 39, the ratios of the profiles F1 to F8 are denoted as reference numerals “J1” to “J8”. In the second embodiment, the ratio between the integrated values is determined as the characteristic value of the profile.

A comparison among the ratios J1 to J8 proves that the ratios J1 to J8 can be categorized into large-value ratios and small-value ratios depending on the layout of the channels. The reason will be discussed below.

The four ratios J1 to J4 (the left side of FIG. 39) out of the ratios J1 to J8 will be first examined below.

The channels CH1 and CH2 are arranged in the z direction with respect to the center position zc, whereas the channels CH3 and CH4 are arranged in the −z direction with respect to the center position zc. Thus, in the range zc-zb, the channels CH1 and CH2 have higher sensitivity than the channels CH3 and CH4. For this reason, the integrated value Sb of the profiles F1 and F2 of the channels CH1 and CH2 is larger than the integrated value Sb of the profiles F3 and F4 of the channels CH3 and CH4. In the range za-zc, the channels CH1 and CH2 have lower sensitivity than the channels CH3 and CH4. Thus, the integrated value Sa of the profiles F1 and F2 of the channels CH1 and CH2 is smaller than the integrated value Sa of the profiles F3 and F4 of the channels CH3 and CH4.

This proves that ratios J1 and J2 of the channels CH1 and CH2 are larger than a ratio J of the channels CH3 and CH4.

In the above explanation, the ratios J1 to J4 of the channels CH1 to CH4 were described. This also holds true for the ratios J5 to J8 of the channels CH5 to CH8. The ratios J5 and J6 of the channels CH5 and CH6 are larger than the ratios J7 and J8 of the channels CH7 and CH8.

Thus, it is understood that the channels CH1, CH2, CH5, and CH6 disposed near the end E1 of the liver can be selected by specifying one having a large value from the ratios J1 to J8.

For this selection, the channel selecting unit 82 sorts the ratios J1 to J8 in order of descending value and specifies four of the channels in order of descending value. In this case, the ratios J1, J2, J5, and J6 are specified as four ratios having large values. This can select the channels CH1, CH2, CH5, and CH6 disposed near the end E1 of the liver out of the channels CH1 to CH8.

After the selection of the channels, the process advances to step ST3.

In step ST3, the main scan MS is performed. In the main scan MS, only the output signals of the channels CH1, CH2, CH5, and CH6 are combined to generate a respiratory signal as in the first embodiment.

After that, as in the first embodiment, an allowable range AW for accepting an imaging signal B is set (FIG. 27) based on the respiratory signals of the periods P₁ to Pₘ. If the respiratory signals are not included in the allowable range AW, data is recollected, and then the flow is ended.

In the second embodiment, the pre-scan PS is performed. The profiles F1 to F8 of the channels CH1 to CH8 are calculated based on the MR signal collected by the pre-scan PS. Furthermore, the ratios J1 to J8 of the profiles F1 to F8 are calculated. The values of the ratios J1 to J8 can be categorized into large values and small values, allowing the selection of the channels disposed near the end E1 of the liver based on the ratios J1 to J8. Moreover, even if a coil different from the coil 4 is used, channels disposed near the end E1 of the liver can be selected from the channels of the another coil. This can eliminate the need for registering the channels for each coil used for imaging, thereby also reducing a burden to the maintenance of the database.

In the second embodiment, the ratios (J1 to J8) of the integrated values of the profiles are calculated as the characteristic values of the profiles. However, other characteristic values may be determined instead of the ratios of the integrated values as long as the channels CH1, CH2, CH5, and CH6 can be discriminated from the channels CH3, CH4, CH7, and CH8. For examples, the maximum value of the signal values of the range za-zc and the maximum value of the signal values of the range zc-zb may be calculated and then the ratio of the maximum values may be determined as the characteristic value of the profile.

In the second embodiment, the channel selecting unit 82 selects the four channels CH1, CH2, CH5, and CH6 as channels disposed near the end E1 of the liver. However, instead of selecting all the four channels CH1, CH2, CH5, and CH6, only one, two, or three of the four channels CH1, CH2, CH5, and CH6 may be selected. As described above, with reference to FIG. 21, the respiratory signal can be obtained with a sufficiently reflected movement of the liver in any one of the channels CH1, CH2, CH5, and CH6. Thus, the selection of at least one of the four channels CH1, CH2, CH5, and CH6 can obtain the respiratory signal with a sufficiently reflected movement of the liver.

In the second embodiment, in the pre-scan PS, a magnetic resonance signal is collected from the slice Lc and then the profiles of the channels are created. The magnetic resonance signal may be however collected from a different slice from the slice Lc before the profiles of the channels are created. Alternatively, the magnetic resonance signals may be collected from the multiple slices before the profiles of the channels are created. In the second embodiment, the pre-scan PS that is a two-dimensional scan may be a three-dimensional scan.

### (3) Third Embodiment

A third embodiment will describe a coil 4 having a plurality of coil modes. A hardware configuration in an MR apparatus is identical to that of the first embodiment (FIG. 1) except for the coil 4.

In the third embodiment, depending on the imaging conditions, the coil 4 is configured to receive an MR signal in the following coil modes:
(1) Coil mode M1 (channels CH1+CH2+CH3 30 CH4)
(2) Coil mode M2 (channels CH5+CH6+CH7+CH8)
(3) Coil mode M3 (channels CH1+CH2+CH3+CH4+CH5+CH6+CH7+CH8)

The coil mode M1 is a mode for receiving the MR signal in the four channels CH1 to CH4. The coil mode M2 is a mode for receiving the MR signal in the four channels CH5 to CH8. The coil mode M3 is a mode for receiving the MR signal in the eight channels CH1 to CH8.

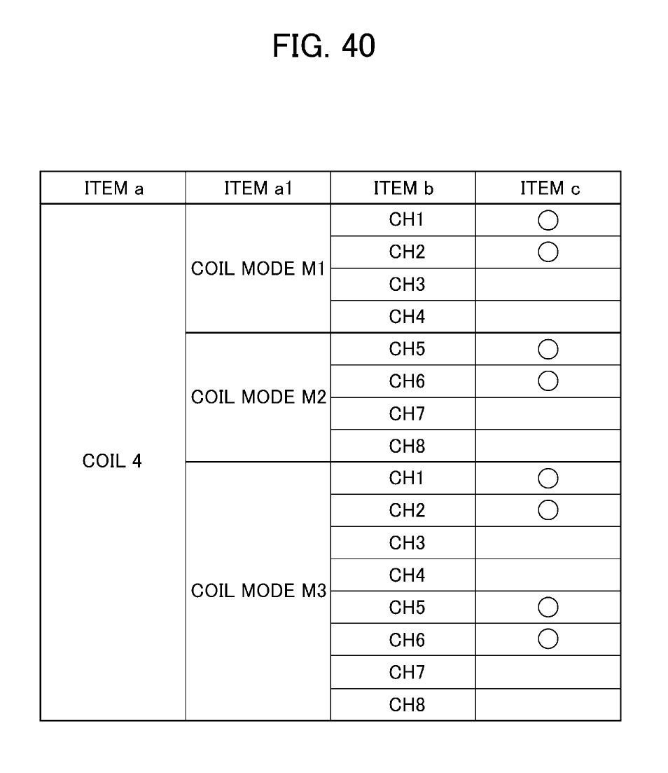

FIG. 40 is a diagram showing a database stored in a memory 9 according to the third embodiment.

Items registered in the database are: a indicating the coil 4, b indicating the channel modes of the coil 4, and c indicating whether the channels are located or not, beside the lungs, near an end E1 of the liver. Circles in the item c indicate that the channels are located near the end E1 of the liver. In this case, the channels CH1, CH2, CH5, and CH6 are registered as channels located near the end E1 of the liver.

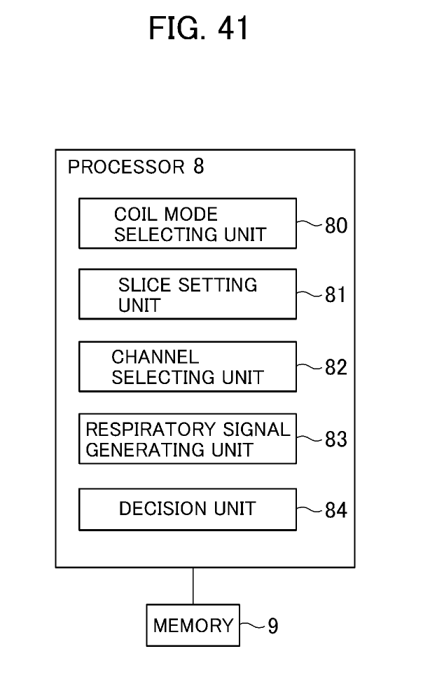

FIG. 41 is an explanatory drawing of processing performed by a processor according to the third embodiment.

A processor 8 reads programs stored in the memory 9 and realizes functions from a coil mode selecting unit 80 to a decision unit 84, and so on.

The coil mode selecting unit 80 selects the coil mode to be used for imaging, from the coil modes M1 to M3 based on information inputted from an operation unit 10.

The slice setting unit 81 sets slices based on the information inputted from the operation unit 10.

The channel selecting unit 82 selects the channel disposed near the end E1 (FIGS. 3A and 3B) of the liver out of the channels CH1 to CH8 included in the selected coil mode, based on the database (FIG. 40).

The respiratory signal generating unit 83 generates a respiratory signal based on the output signal of the channel selected by the channel selecting unit 82.

The decision unit 84 decides whether an imaging signal should be accepted or not as an image reconstruction signal.

The processor 8 performs predetermined programs so as to function as these units.

An operation flow of the MR apparatus according to the third embodiment will be described below.

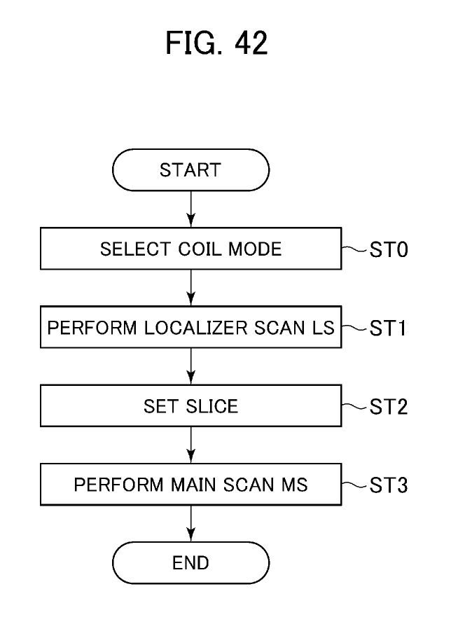

FIG. 42 is a diagram showing the operation flow of the MR apparatus according to the third embodiment.

In step ST0, before a localizer scan LS is performed, an operator operates the operation unit 10 to input information for selecting the coil mode used for imaging a subject out of the coil modes M1 to M3. When the information is inputted, the coil mode selecting unit 80 (FIG. 41) selects the coil mode used for imaging the subject out of the coil modes M1 to M3 based on the information inputted from the operation unit 10. In this case, the coil M1 is selected. After the selection of the coil mode M1, the process advances to step ST1.

In step ST1, the localizer scan LS is performed using the coil mode M1. An image D (FIG. 7) is obtained by performing the localizer scan LS.

In step ST2, the operator sets slices L1 to Ln (FIG. 8) based on the image D. After the slices L1 to Ln are set, the process advances to step ST3.

In step ST3, a main scan MS is performed.

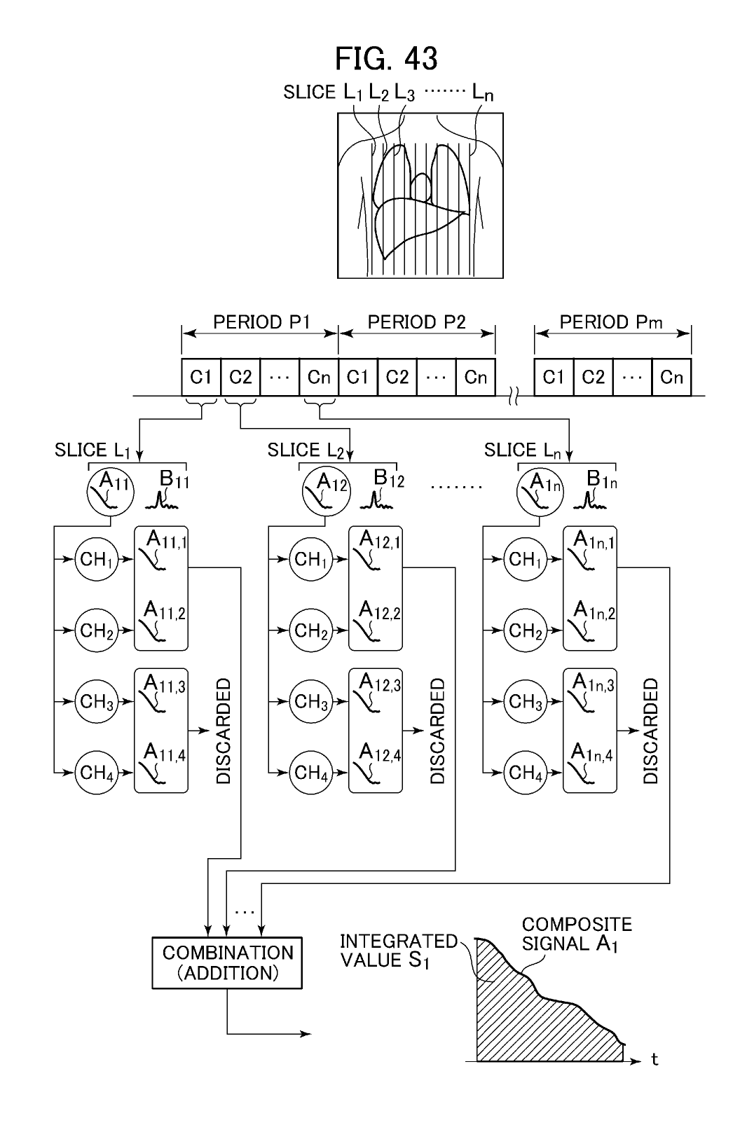

FIG. 43 is an explanatory drawing of the main scan MS according to the third embodiment.

In the period P₁, a sequence C1 is first performed. A DC signal A₁₁ and an imaging signal B₁₁ are collected from the slice L1 by performing the sequence C1.

In the third embodiment, the coil mode M1 is selected and thus the DC signal A₁₁ and the imaging signal B₁₁ are received by each of the channels CH1 to CH4 of the coil mode M1. For convenience of explanation, FIG. 43 only shows a state in which the DC signal A₁₁ is received by each of the channels CH1 to CH4 of the coil mode M1. The channels CH1 to CH4 output signals A_{11,1} to A_{11,4}, respectively.

After the execution of the sequence C1, a sequence C2 is performed. A DC signal A₁₂ and an imaging signal B₁₂ are collected from the slice L2 by performing the sequence C2.

The DC signal A₁₂ and the imaging signal B₁₂ are received by each of the channels CH1 to CH4 of the coil mode M1. For convenience of explanation, FIG. 43 only shows a state in which the DC signal A₁₂ is received by each of the channels CH1 to CH4. The channels CH1 to CH4 output signals A_{12,1} to A_{12,4,} respectively.

After that, the sequences for collecting the DC signals and the imaging signals from each of the slices L3 to Ln are performed in a similar manner. At the end of the period P₁, the sequence Cn for collecting data on the slice Ln is performed. The DC signal A₁ₙ and the imaging signal B₁ₙ are collected from the slice Ln by performing the sequence Cn.

The DC signal A₁ₙ and the imaging signal B₁ₙ are received by each of the channels CH1 to CH4 of the coil mode M1. For convenience of explanation, FIG. 43 only shows a state in which the DC signal A₁ₙ is received by each of the channels CH1 to CH4 of the coil mode M1. The channels CH1 to CH4 output signals A_{1n,1} to A_{1n,4}, respectively.

After the sequences C1 to Cn are performed in a period P₁, a respiratory signal is generated as follows:

First, the channel selecting unit 82 (FIG. 41) refers to a database (FIG. 40). Furthermore, the channel selecting unit 82 selects the channels CH1 and CH2 registered as channels disposed near the end E1 of the liver, out of the channels CH1 to CH4 of the coil mode Ml based on information in item c of the database.

Subsequently, the respiratory signal generating unit 83 (FIG. 41) discards the output signals of the unselected channels CH3 and CH4 out of the channels CH1 to CH4 of the coil mode M1 and combines (adds) only the output signals of the selected channels CH1 and CH2. Thus, a composite signal A1 is obtained.

After the composite signal A₁ is obtained, the respiratory signal generating unit 83 calculates an integrated value S₁ of the composite signal A₁. The integrated value S₁ is used as a signal value of the respiratory signal of a subject in the period P₁.

After that, the sequences C1 to Cn are similarly performed in periods P₂ to Pₘ. The respiratory signal generating unit 83 discards the output signals of the channels CH3 and CH4 and combines (adds) the output signals of the selected channels CH1 and CH2. Moreover, the respiratory signal generating unit 83 calculates the integrated value of the composite signal. This can obtain the respiratory signals in the periods P₁ to Pₘ.

After that, as in the first embodiment, an allowable range AW for accepting an imaging signal B is set (FIG. 27) based on the respiratory signals of the periods P₁ to Pₘ. If the respiratory signals are not included in the allowable range AW, data is recollected, and then the flow is ended.

In the third embodiment, the channels disposed near the end E1 of the liver are associated with each of the coil modes (FIG. 40). Thus, in any one of the coil modes, the satisfactory respiratory signal can be obtained with a reflected movement of the liver.

### (4) Fourth Embodiment

In a fourth embodiment, a coil 4 has coil modes M1 to M3 as in the third embodiment. In the example of the fourth embodiment, however, channels are selected using the pre-scan PS (FIG. 32) of the second embodiment without being registered in a database. The hardware configuration of an MR apparatus is identical to that of the first embodiment (FIG. 1) except for the coil 4.

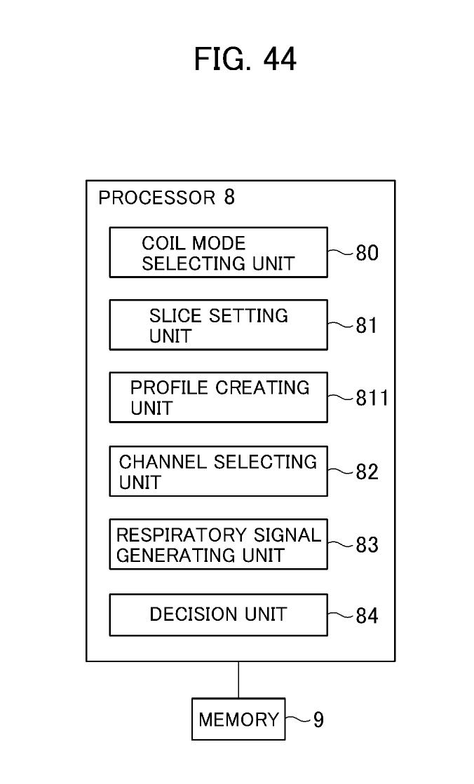

FIG. 44 is an explanatory drawing of processing performed by a processor according to the fourth embodiment.

A processor 8 reads programs stored in a memory 9 and realizes functions from a coil mode selecting unit 80 to decision unit 84, and so on.

The coil mode selecting unit 80 selects the coil mode to be used for imaging, from the coil modes M1 to M3 based on information inputted from an operation unit 10.

The slice setting unit 81 sets slices based on the information inputted from the operation unit 10.

A profile creating unit 811 creates profiles indicating the relationship between positions in the z direction of an imaged part and signal strength based on an MR signal collected by the pre-scan PS.

The channel selecting unit 82 selects a channel disposed near an end E1 (FIG. 3) of a liver out of channels included in the selected coil mode, based on the profiles created by the profile creating unit 811.

The respiratory signal generating unit 83 generates a respiratory signal based on the output signal of the channel selected by the channel selecting unit 82.

The decision unit 84 decides whether an imaging signal should be accepted or not as an image reconstruction signal.

The processor 8 performs predetermined programs so as to function as these units.

An operation flow of the MR apparatus according to the fourth embodiment will be described below.

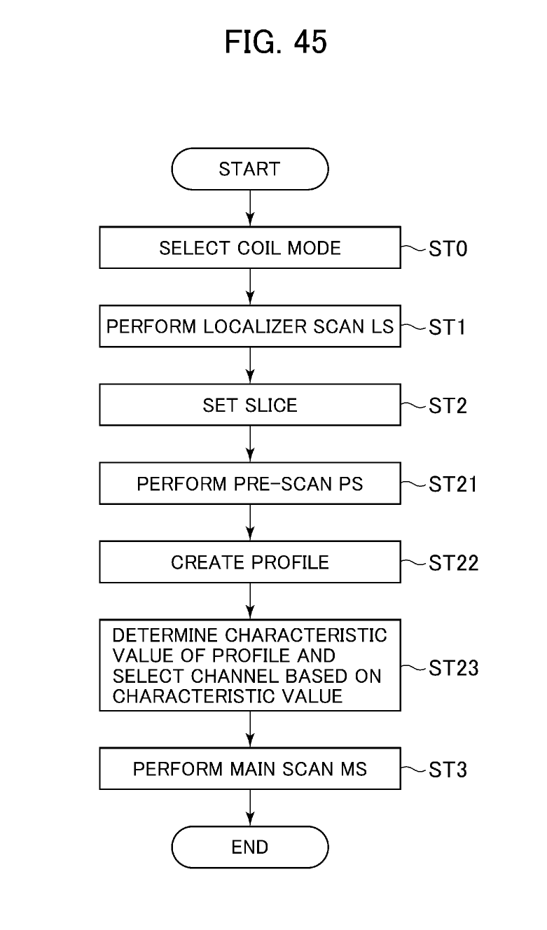

FIG. 45 is a diagram showing the operation flow of the MR apparatus according to the fourth embodiment.

In step ST0, the coil mode is selected. It is assumed that the coil mode M1 is selected in the fourth embodiment as in the third embodiment. After the coil mode M1 is selected, the process advances to step ST1.

Step ST1 and step ST2 are identical to those of the third embodiment and thus the detailed explanation thereof is omitted. In step ST2, slices L1 to Ln (FIG. 8) are set, and then the process advances to step ST21.

In step ST21, the pre-scan PS is performed using the coil mode M1.

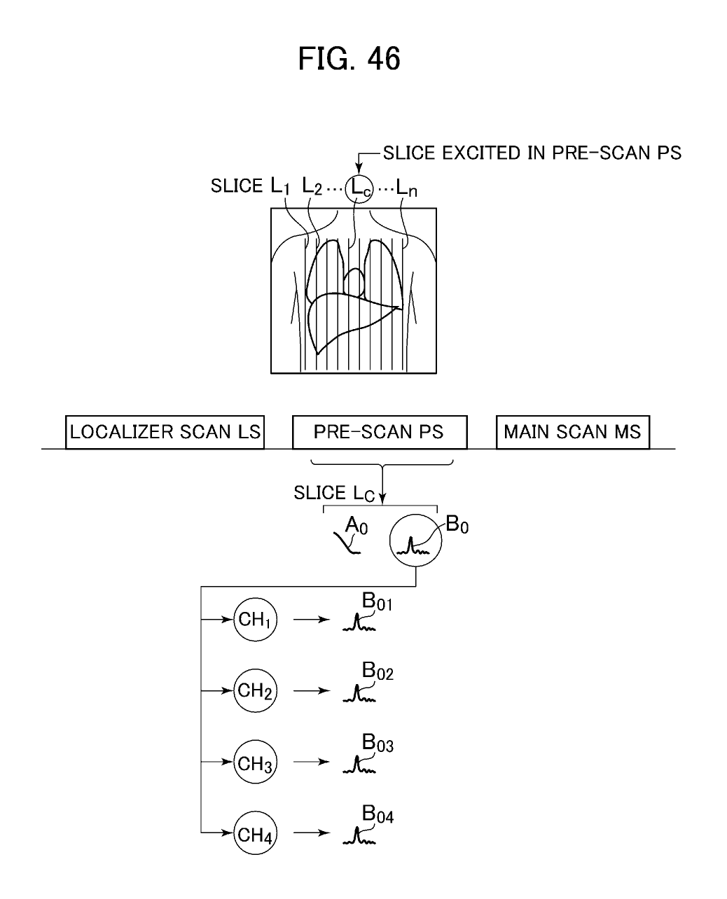

FIG. 46 is an explanatory drawing of the pre-scan PS.

In the pre-scan PS, only one of the slices L1 to Ln is excited, and a are collected from the excited slice. In the second embodiment, the central slice Lc of the slices L1 to Ln is excited. Thus, the DC signal A0 and the imaging signal B0 are collected from the slice Lc.

In the fourth embodiment, the coil mode M1 is selected and thus the DC signal A0 and the imaging signal B0 are received by each of channels CH1 to CH4. For convenience of explanation, FIG. 46 only shows the imaging signal B0 received by each of the channels CH1 to CH4 of the coil mode M1. Of the DC signal A₀ and the imaging signal B₀, the imaging signal B₀ is used for selecting the channels while the DC signal A₀ is not used for selecting the channels.

The channels CH1 to CH4 respectively output the signals _{B01} and B₀₄ in response to the imaging signal B₀ received by the channels CH1 to CH4.

After the pre-scan PS is performed, the process advances to step ST22.

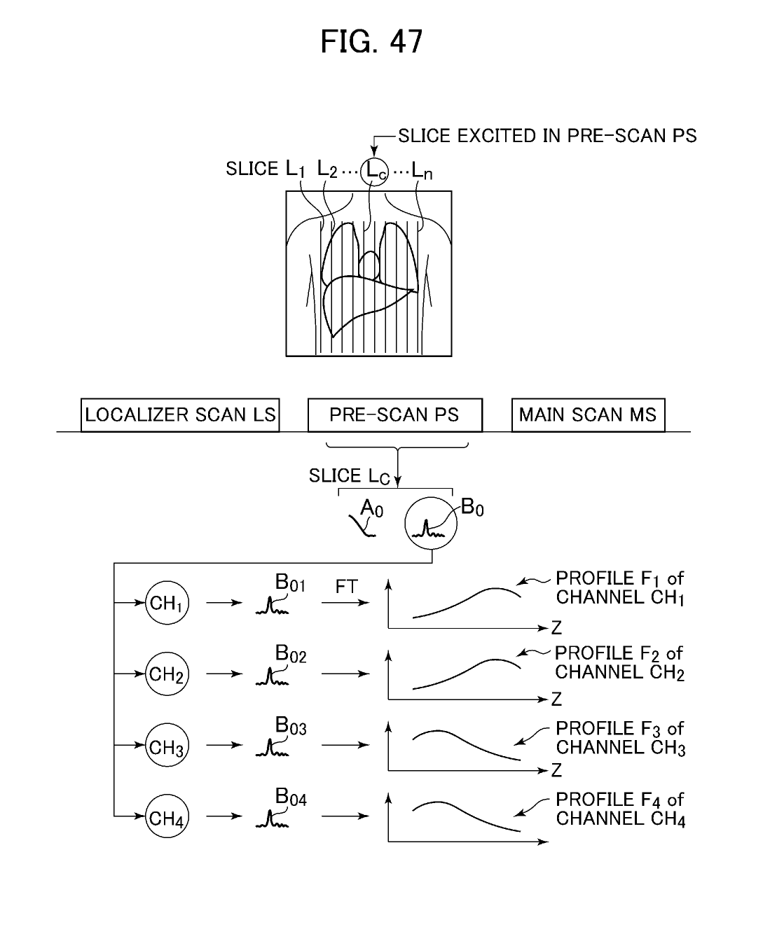

In step ST22, the profile creating unit 811 (FIG. 44) performs Fourier transformation (FT) on the output signals B01 to B08 of the channels CH1 to CH8 in the z direction. Thus, as shown in FIG. 47, profiles F1 to F4 are created.

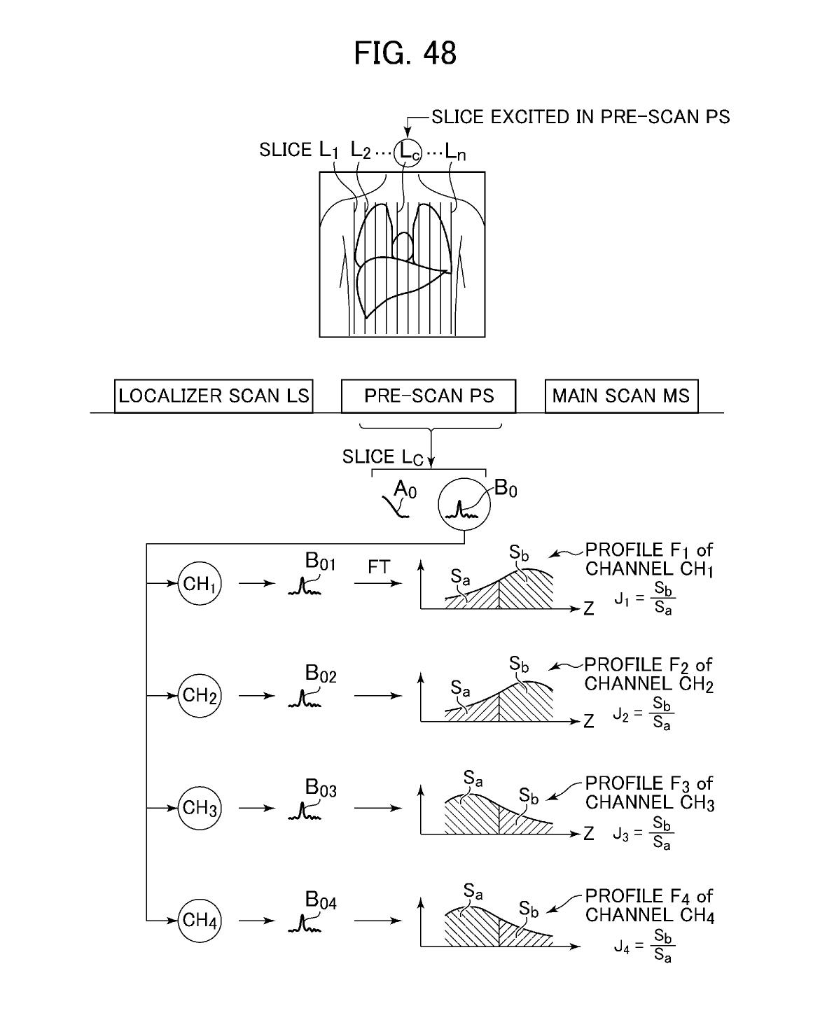

After the profiles F1 to F4 are created, the ratio of integrated values Sb and Sa is calculated for each profile. Reference numerals “J1” to “J4” in FIG. 48 denote the ratios of the profiles F1 to F4.

The channel selecting unit 82 (FIG. 44) sorts the ratios J1 to J4 in order of descending value and specifies two of the channels in order of descending value. This can select the channels CH1 and CH2 disposed near the end E1 of the liver out of the channels CH1 to CH4.

After the selection of the channels, the process advances to step ST3.

In step ST3, a main scan MS is performed. The main scan MS in the fourth embodiment is performed in the same steps as the main scan MS of the third embodiment (FIG. 43).

In the fourth embodiment, as in the third embodiment, the satisfactory respiratory signal can be obtained with a reflected movement of the liver in any one of the coil modes.

In the fourth embodiment, the pre-scan PS is performed and the channels disposed near the end E1 of the liver are selected based on the MR signal collected by the pre-scan PS. This eliminates the need for registering the channels in each of the coil modes used for imaging, thereby also reducing a burden to the maintenance of the database.

In the fourth embodiment, a magnetic resonance signal is collected from the slice Lc in the pre-scan PS and then the profiles of the channels are created. The magnetic resonance signal may be however collected from a different slice from the slice Lc before the profiles of the channels are created. Alternatively, magnetic resonance signals may be collected from the multiple slices before the profiles of the channels are created. In the fourth embodiment, the pre-scan PS that is a two-dimensional scan may be a three-dimensional scan.

In the third and fourth embodiments, the coil mode selecting unit 80 selects the coil mode based on the information inputted from the operation unit 10 by an operator. However, the coil mode selecting unit may automatically select the coil mode using a technique of auto coil selection.

In the first to fourth embodiments, the signals received by the channels are added to obtain the composite signal. However, the combination of the signals is not limited to addition. For example, the signals may be subjected to weighting addition into the composite signal or the signals may be multiplied to obtain the composite signal. Furthermore, in the first to fourth embodiments, the integrated vale of the composite signal is used as a signal value of the respiratory signal. However, the signal value of the respiratory signal may be a different value (e.g., the maximum value of the composite signal) from the integrated value of the composite signal.

In the first to fourth embodiments, the respiratory signal is generated based on the DC signal indicating data at the center of the k space. However, the respiratory signal may be generated based on a different MR signal from the DC signal.

In the first to fourth embodiments, the main scan MS that is a two-dimensional scan may be a three-dimensional scan.

The first to fourth embodiments describe examples of the acquisition of the respiratory signal. However, the disclosure is not limited to the acquisition of the respiratory signal. For example, in the case of imaging of a heart, a biological signal including information on heart beats can be obtained.

Many widely different embodiments may be configured without departing from the spirit and the scope of the invention. It should be understood that the invention is not limited to the specific embodiments described in the specification, except as defined in the appended claims.

1. A magnetic resonance apparatus for performing a scan for generating a first magnetic resonance signal from an imaged part including a moving part,
the magnetic resonance apparatus comprising:
a coil having a plurality of channels configured to receive the first magnetic resonance signal;
a channel selecting unit configured to select a first channel disposed near an end of the moving part from the plurality of channels; and
a generating unit configured to generate a biological signal including motion information indicating a movement of the imaged part in the scan, based on the first magnetic resonance signal received by the first channel.

2. The magnetic resonance apparatus according to claim 1, wherein the channel selecting unit is configured to select the first channel from the plurality of channels based on a database containing information for specifying the channel disposed near the end of the moving part.

3. The magnetic resonance apparatus according to claim 2, wherein the channel selecting unit is configured to select at least two first channels from the plurality of channels based on the database, and wherein the generating unit is configured to combine the first magnetic resonance signal received by each of the at least two first channels and generate the biological signal based on a composite signal obtained by the signal combination.

4. The magnetic resonance apparatus according to claim 1, wherein the plurality of channels include a second channel located farther from the end of the moving part than the first channel, and wherein the first magnetic resonance signal received by the second channel is not used for generating the biological signal.

5. The magnetic resonance apparatus according to claim 1, wherein the coil has a plurality of coil modes, each coil mode including at least one of the channels.

6. The magnetic resonance apparatus according to claim 5, further comprising a coil mode selecting unit configured to select a first coil mode used for receiving the first magnetic resonance signal, from the plurality of coil modes included in the coil, the first coil mode having the first channel.

7. The magnetic resonance apparatus according to claim 6, wherein the first coil mode has a second channel located farther from the end of the moving part than the first channel, and wherein the first magnetic resonance signal received by the second channel is not used for generating the biological signal.

8. The magnetic resonance apparatus according to claim 1, further configured to perform another scan for generating a second magnetic resonance signal from the imaged part before the scan, and
a profile creating unit configured to create, for each of the channels, a profile indicating a signal value at each position in a predetermined direction of the imaged part based on the second magnetic resonance signal collected for each of the channels of the coil in the another scan,
wherein the channel selecting unit is configured to select the first channel from the plurality of channels based on the profile.

9. The magnetic resonance apparatus according to claim 8, wherein the channel selecting unit is configured to select at least two first channels from the plurality of channels based on the profile, and
wherein the generating unit is configured to combine the first magnetic resonance signal received by each of the at least two first channels and generate the biological signal based on a composite signal obtained by the signal combination.

10. The magnetic resonance apparatus according to claim 8, wherein the plurality of channels include a second channel located farther from the end of the moving part than the first channel, and wherein the first channel and the second channel are located at different positions in the predetermined direction.

11. The magnetic resonance apparatus according to claim 8, wherein the channel selecting unit is configured to calculate a characteristic value indicting a characteristic of the profile and select the first channel based on the characteristic value.

12. The magnetic resonance apparatus according to claim 11, wherein the channel selecting unit is configured to divide a range of the profile in the predetermined direction into a first range and a second range, calculate a first integrated value in the first range and a second integrated value in the second range, and calculate the characteristic value based on the first integrated value and the second integrated value.

13. The magnetic resonance apparatus according to claim 8, wherein the second magnetic resonance signal is configured to be generated, in the another scan, from a slice crossing the imaged part, and wherein the slice is parallel to the predetermined direction.

14. The magnetic resonance apparatus according to claim 13, wherein the slice is a sagittal slice.

15. The magnetic resonance apparatus according to claim 8, wherein the coil has a plurality of coil modes, each including at least one of the channels.

16. The magnetic resonance apparatus according to claim 15, further comprising a coil mode selecting unit configured to select a first coil mode used for receiving the first magnetic resonance signal and the second magnetic resonance signal, from the plurality of coil modes included in the coil, the first coil mode having the first channel.

17. The magnetic resonance apparatus according to claim 16, wherein the first coil mode has the second channel located farther from the end of the moving part than the first channel, and wherein the first magnetic resonance signal received by the second channel is not used for generating the biological signal.

18. The magnetic resonance apparatus according to claim 1, wherein in the scan, a third magnetic resonance signal for reconstructing an image of the imaged part is generated from the imaged part.

19. The magnetic resonance apparatus according to claim 18, further comprising a decision unit configured to decide whether the third magnetic resonance signal should be accepted as a signal for image reconstruction based on the biological signal.

20. The magnetic resonance apparatus according to claim 1, wherein the first magnetic resonance signal is a signal indicating data at a center of a k space.

21. The magnetic resonance apparatus according to claim 1, wherein the moving part is a liver, and wherein the end of the moving part is an end of the liver near a lung.

22. The magnetic resonance apparatus according to claim 1, wherein the moving part is a liver, and wherein the end of the moving part is an end of the liver on an opposite side from a lung.

23. The magnetic resonance apparatus according to claim 1, wherein the biological signal is a respiratory signal.

24. A method for generating a first magnetic resonance signal from an imaged part including a moving part, the method comprising:
receiving the first magnetic resonance signal using a coil having a plurality of channels;
selecting a first channel disposed near an end of the moving part from the plurality of channels; and
generating a biological signal including motion information indicating a movement of the imaged part in a scan, based on the first magnetic resonance signal received by the first channel.
